(19) United States
(12) Patent Application Publication
(10) Pub. No.: US 2022/0037519 A1
(43) Pub. Date: Feb. 3, 2022

(54) TRANSISTOR STRUCTURES AND ASSOCIATED PROCESSES

(71) Applicant: Fu-Chang Hsu, San Jose, CA (US)

(72) Inventor: Fu-Chang Hsu, San Jose, CA (US)

(21) Appl. No.: 17/389,241

(22) Filed: Jul. 29, 2021

Related U.S. Application Data
(60) Provisional application No. 63/058,479, filed on Jul. 29, 2020.
(60) Provisional application No. 63/133,298, filed on Jan. 2, 2021.
(60) Provisional application No. 63/182,828, filed on May 1, 2021.
(60) Provisional application No. 63/182,933, filed on May 1, 2021.
(60) Provisional application No. 63/184,063, filed on May 4, 2021.
(60) Provisional application No. 63/186,150, filed on May 9, 2021.

(51) Int. Cl. H01L 29/78; H01L 29/08; H01L 29/06

(52) U.S. Cl. CPC H01L 29/78; H01L 29/0642; H01L 29/0847

(57) ABSTRACT

Transistor structures and associated processes are disclosed. In an exemplary embodiment, a transistor structure is provided that includes a conductor layer divided into a plurality of separate conductor regions and a plurality of lateral transistors formed on top of the plurality of separate conductor regions, respectively. Each lateral transistor comprises a source, a drain, and a gate region, and at least one of the source, drain, and gate regions of each lateral transistor is conductively coupled underneath to its respective conductor region.

### CROSS-REFERENCE TO RELATED APPLICATIONS

This application claims the benefit of priority based upon U.S. Provisional Patent Application having Application No. 63/186,150 filed on May 9, 2021 and entitled “MFET—NOVEL TRANSISTOR STRUCTURE AND PROCESS,” and U.S. Provisional Patent Application having Application No. 63/184,063, filed on May 4, 2021 and entitled “XCFET—NOVEL TRANSISTOR STRUCTURE AND PROCESS,” and U.S. Provisional Patent Application having Application No. 63/182,933 filed on May 1, 2021 and entitled “NOVEL TRANSISTOR STRUCTURE AND PROCESS,” and U.S. Provisional Patent Application having Application No. 63/182,828 filed on May 1, 2021, and entitled “NOVEL TRANSISTOR STRUCTURE AND PROCESS,” and U.S. Provisional Patent Application having Application No. 63/133,298 filed on Jan. 2, 2021 and entitled “NOVEL TRANSISTOR AND METAL LAYER STRUCTURE AND PROCESS,” and U.S. Provisional Patent Application having Application No. 63/058,479 filed on Jul. 29, 2020 and entitled “NOVEL ADVANCED FIELD-EFFECT TRANSISTOR,” all of which are hereby incorporated herein by reference in their entireties.

### FIELD OF THE INVENTION

The exemplary embodiments of the present invention relate generally to the field of semiconductors, and more specifically to transistor structures and associated processes.

### BACKGROUND OF THE INVENTION

With the increasing complexity and density of electronic circuits, overall device size has become an important consideration. For example, semiconductor devices include not only large amounts of electronic circuity, but also power and grounding systems to electrify those circuits. Current conventional technologies have power and grounding systems that occupy a considerable amount of the silicon area available on the device. Therefore, it is desirable to have a structure that can be used to reduce the amount of silicon area utilized by the power and grounding systems thereby making more silicon area of the device available for circuitry.

### SUMMARY

In various exemplary embodiments, transistor structures and associated processes are disclosed. Transistor devices may be implemented in many advanced technologies, such as multi-bridge-channel field-effect transistor (MBCFET), gate-all-around field-effect transistor (GAAFET), nanowire field-effect transistor (NWFET), FinFET, and many others. These transistor devices are used below 10 nanometers (nm) to reduce channel leakage and to reduce the device size. In various embodiments, novel transistor device structures called “power-under-device” or “device-over-power” are disclosed. In these structures, the power lines are located directly under the transistor devices to reduce the amount of silicon area utilized by the power lines to allow smaller and denser devices to be produced.

In an exemplary embodiment, a transistor structure is provided that includes a conductor layer divided into a plurality of separate conductor regions and a plurality of lateral transistors formed on top of the plurality of separate conductor regions, respectively. Each lateral transistor comprises a source, a drain, and a gate region, and at least one of the source, drain, and gate regions of each lateral transistor is conductively coupled underneath to its respective conductor region.

In an exemplary embodiment, a transistor structure is provided that includes a conductor layer divided into a plurality of separate conductor regions and two lateral transistors formed on top of each of the plurality of separate conductor regions, respectively. Each lateral transistor comprises a source, a drain, and a gate region, and at least one of the source, drain, and gate regions of each lateral transistor is conductively coupled underneath to its respective conductor region.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIG. 1A shows an exemplary embodiment of a four lateral transistor structure constructed according to the invention.

FIG. 1B shows another exemplary embodiment of a four lateral transistor structure constructed according to the invention.

FIG. 1C shows an exemplary embodiment of a transistor structure constructed according to the invention.

FIG. 1D shows an embodiment of a transistor array structure that comprises the transistor structure shown in FIG. 1A.

FIG. 1E shows another embodiment of a transistor array structure that comprises the transistor structure shown in FIG. 1B.

FIGS. 2A-G show exemplary embodiments of transistor power line connections.

FIGS. 3A-D show additional exemplary embodiments of a gate and channel structures of transistor structures constructed according to the invention.

FIGS. 4A-T show exemplary embodiments of process steps used to form the transistor structure shown in FIG. 1B.

FIG. 4U shows the results of a process step in which a common gate structure is formed.

FIGS. 4V-Y shows exemplary embodiments of process steps using ‘metal-replacement’ technology in accordance with the invention.

FIGS. 5A-H show exemplary embodiments of process steps used to form the transistor structure shown in FIG. 1A in accordance with the invention.

FIGS. 6A-G shows exemplary detailed process steps for forming the channels and the gates of the transistor structure as described with respect to FIGS. 4N-S.

FIGS. 7A-E shows exemplary embodiments of a transistor structure according to the invention.

FIGS. 8A-B show exemplary embodiments of a transistor structure constructed according to the invention.

FIG. 9A-C show exemplary embodiments of a transistor structure constructed according to the invention.

FIGS. 10A-B shows exemplary embodiments of an inverter circuit constructed using embodiments of the transistor structure described herein.

FIGS. 11A-B show embodiments of a NAND logic gate using embodiments of the transistor structure describe herein.

FIGS. 12A-C show embodiments of a static random-access memory (SRAM) cell constructed using the transistor structure described herein in accordance with the invention.

FIG. 13A to FIG. 17 shows additional exemplary embodiments of transistor structures constructed using a ‘non-self-aligned’ process according to the invention.

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

For simplicity, exemplary embodiments described below will use MBCFET transistor structures as examples. However, aspects of the invention are not limited to use with only these devices. Thus, various novel aspects of the invention can be applied to any other suitable transistor devices to allow smaller and denser devices to be produced. The structures and processes disclosed herein meet current most-advanced 1-3 nm processes and can be applied to any future smaller process node.

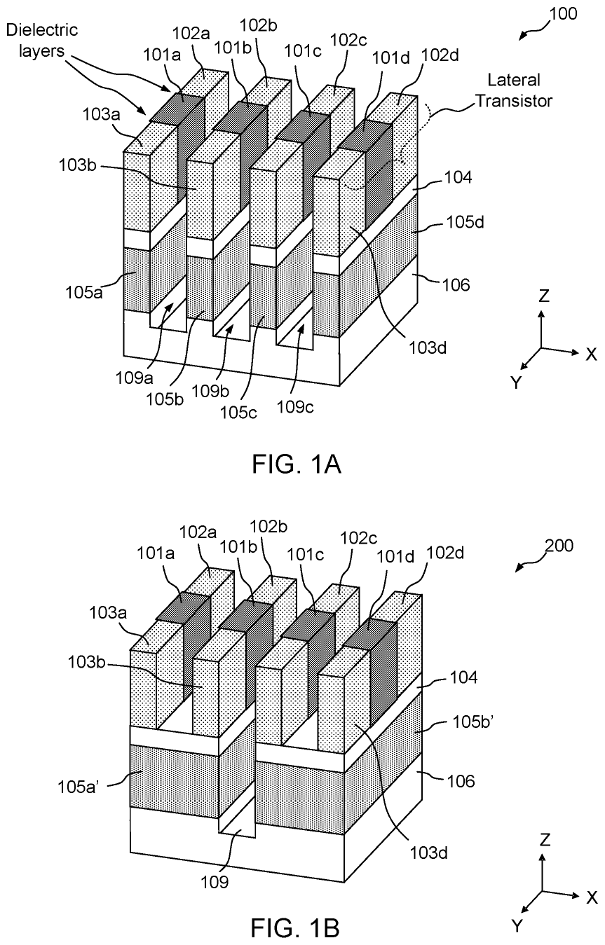

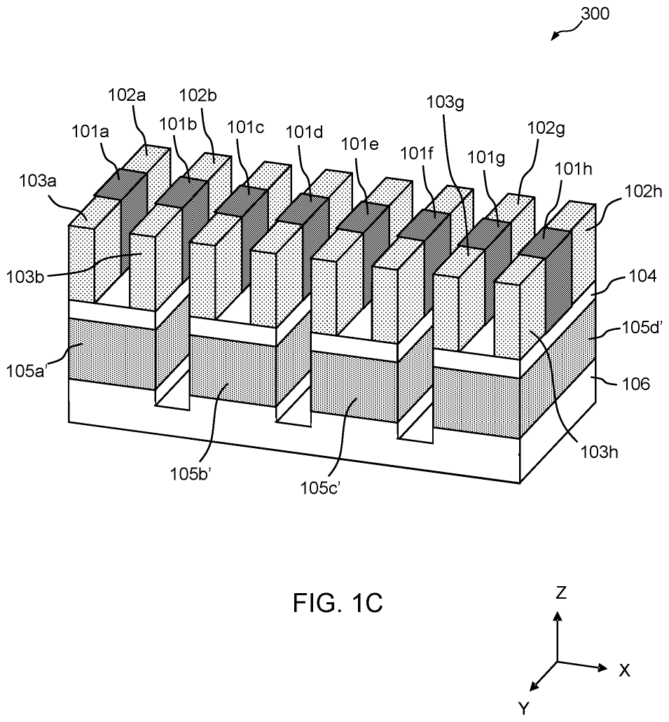

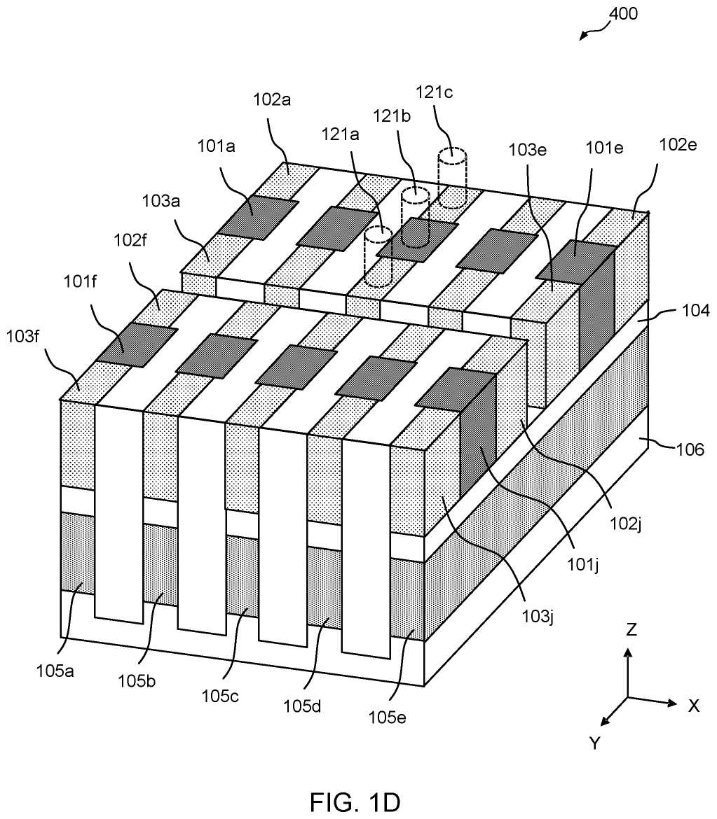

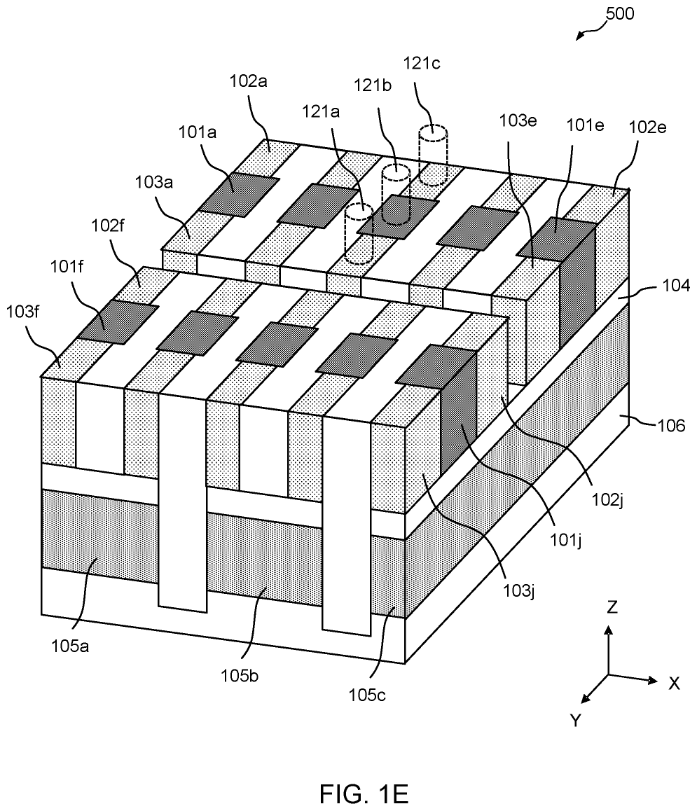

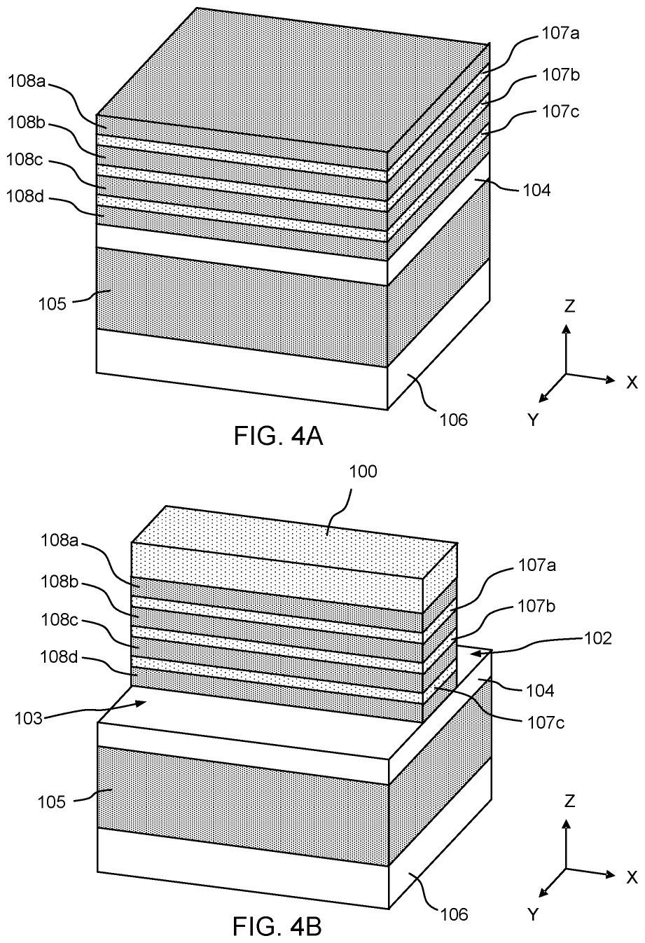

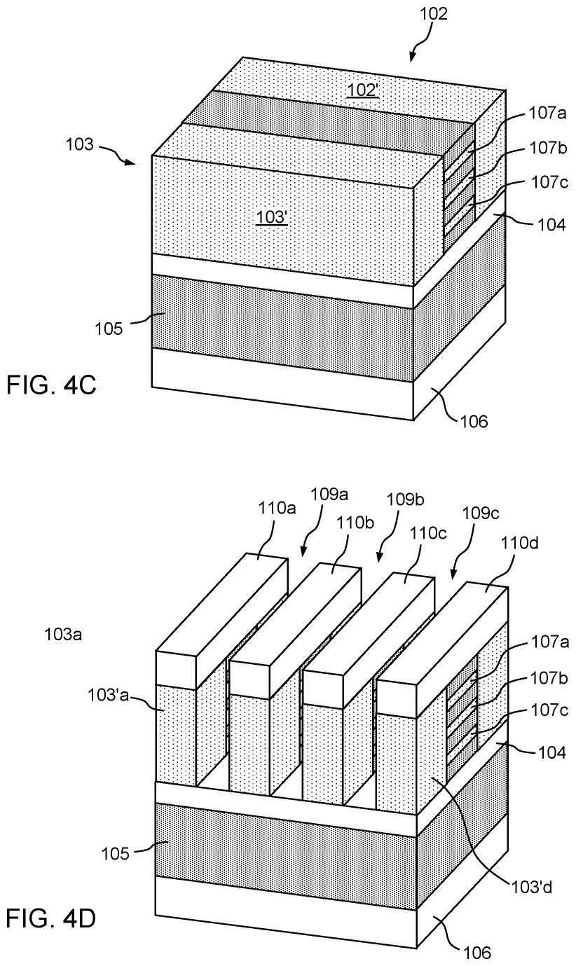

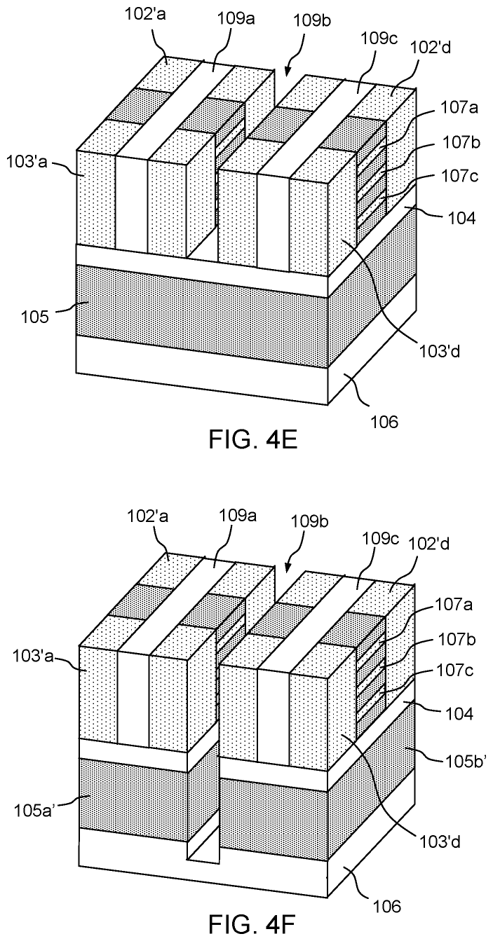

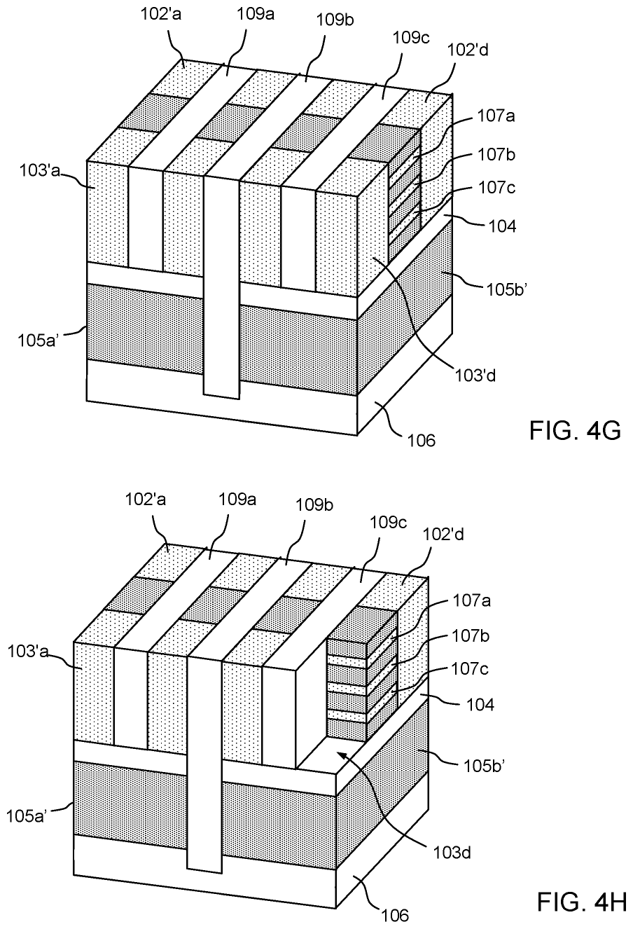

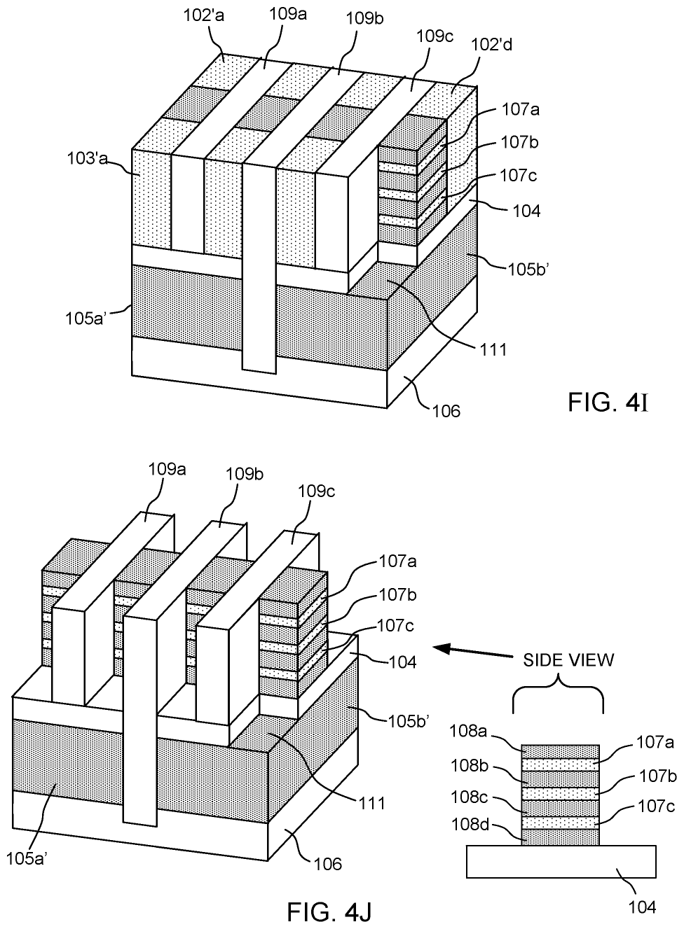

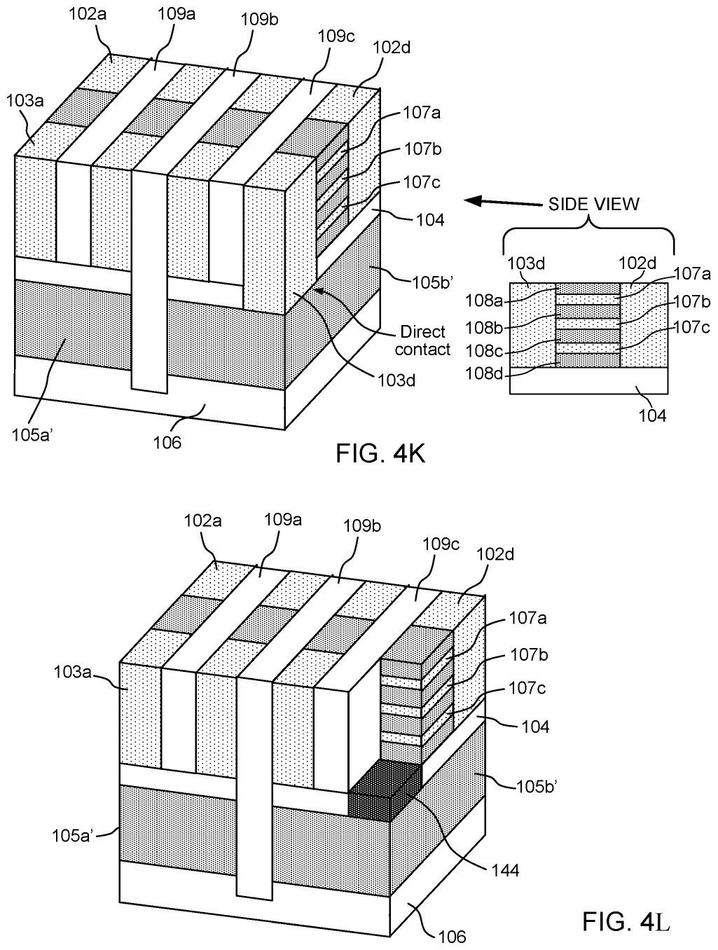

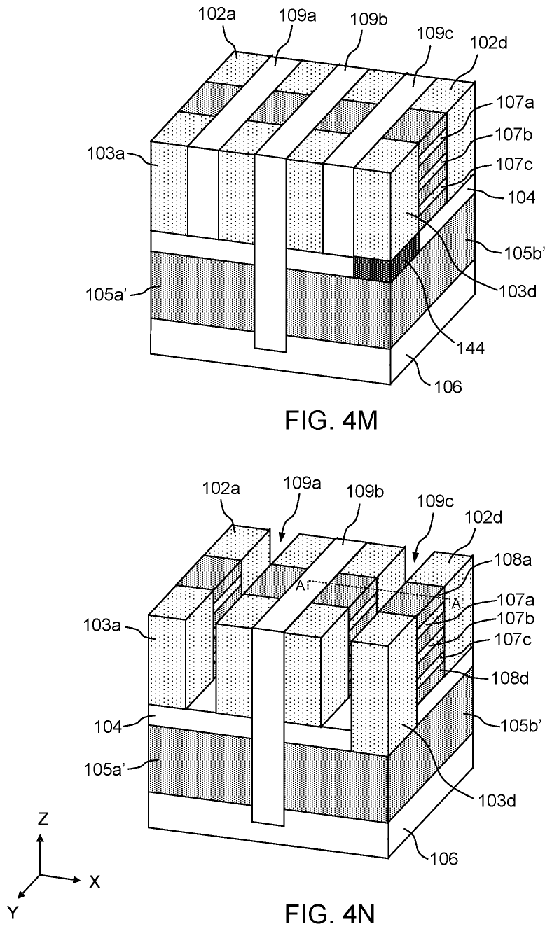

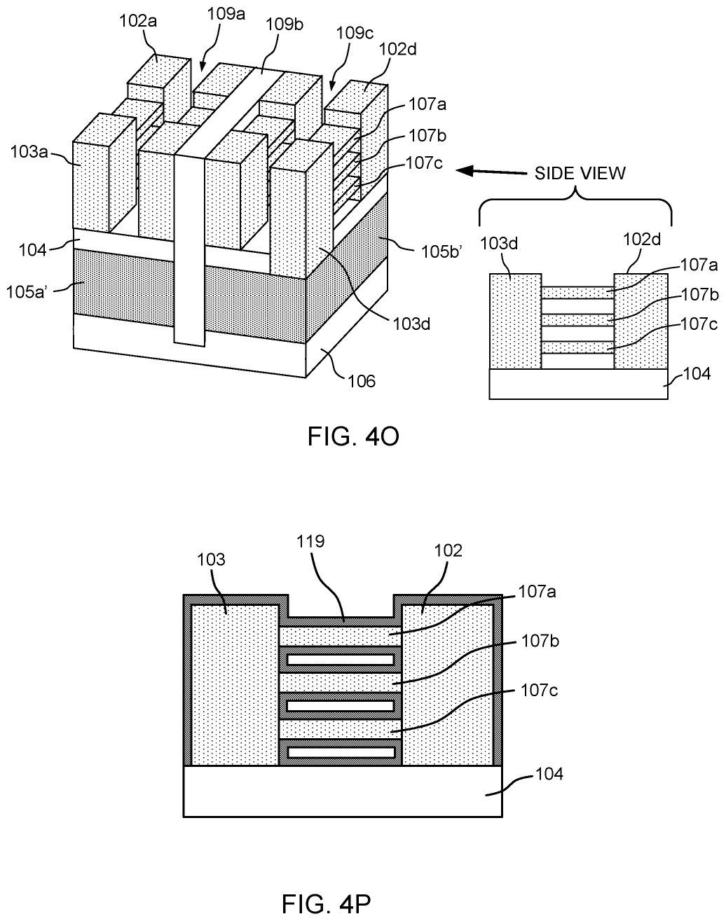

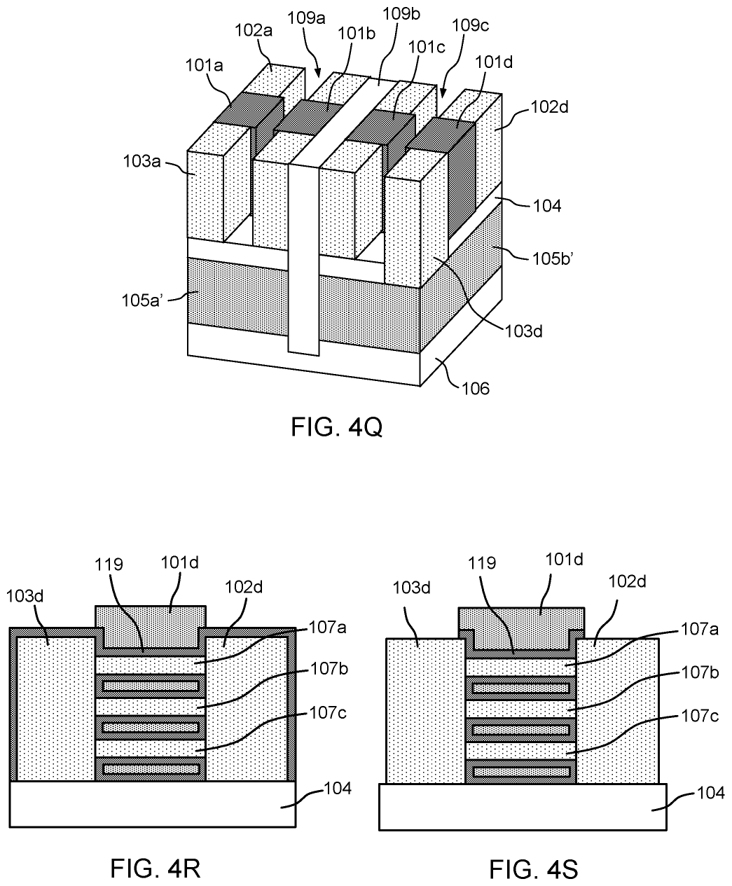

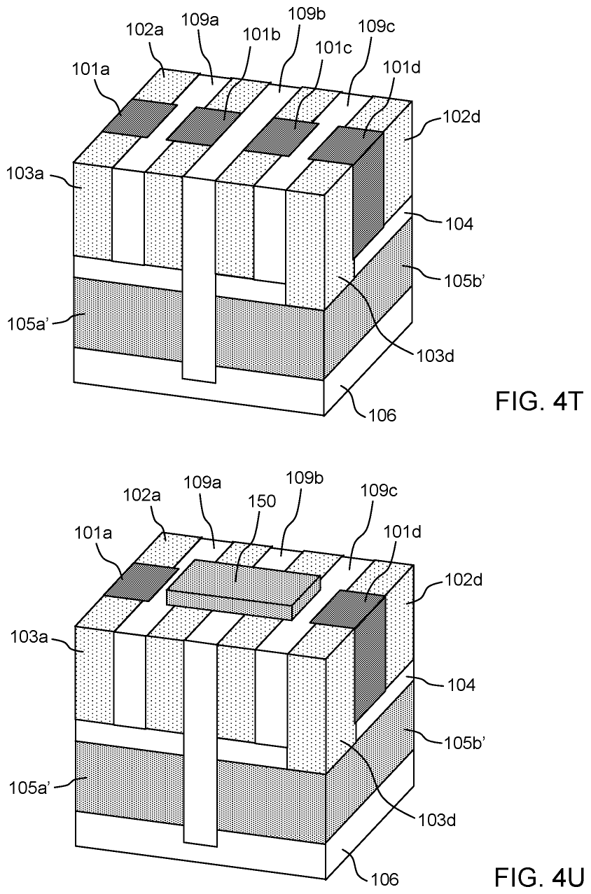

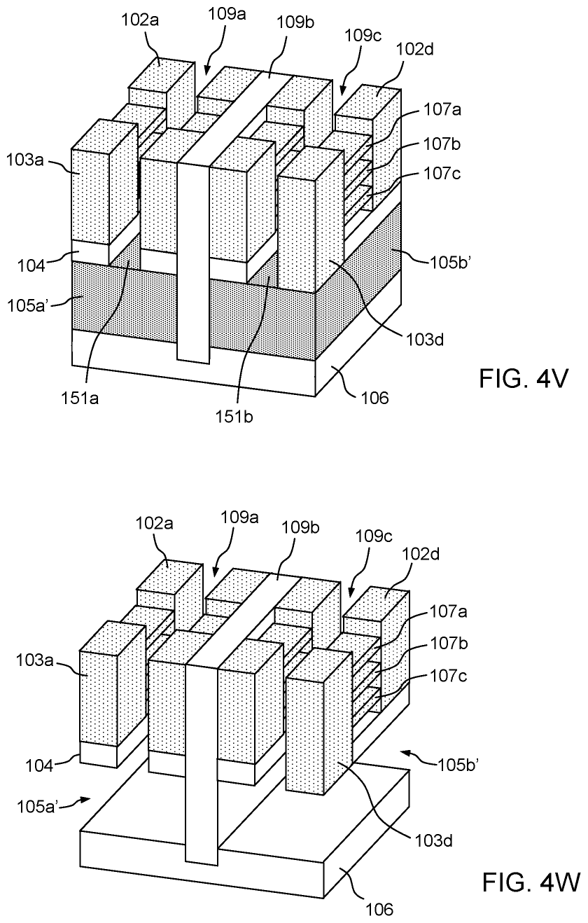

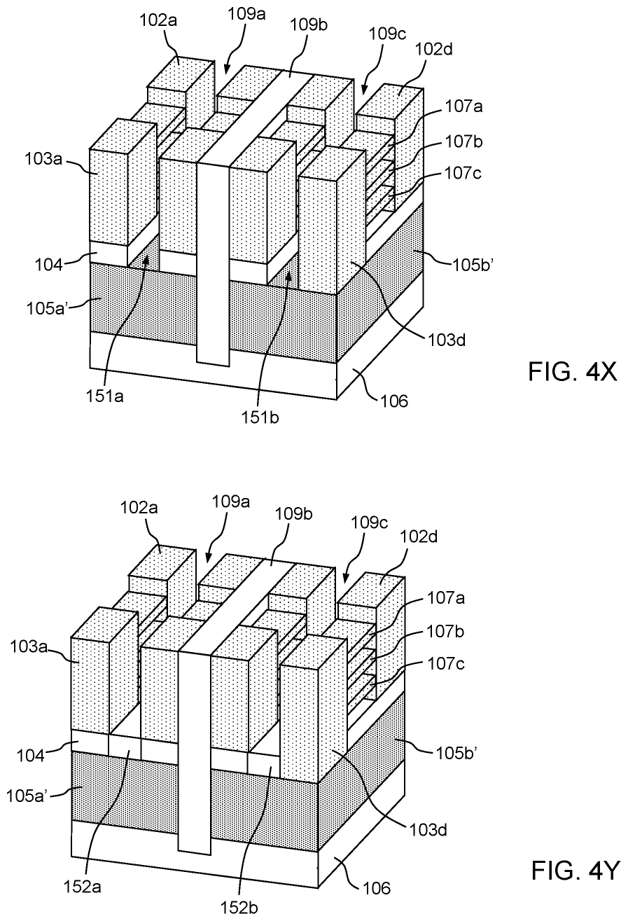

FIG. 1A shows an exemplary embodiment of a four lateral transistor structure 100 constructed according to the invention. The structure 100 includes control gates 101a-d, which can be formed from conducting material, such as metal or polysilicon. Channels of the transistors are formed inside the control gates 101a-d. Depending on the transistor type, the channels may have different shapes. Additional details for the channels are provided in the process steps shown in FIG. 4A-T.

The structure 100 also includes source regions 102a-d, and drain regions 103a-d. In one embodiment, the sources and drain regions are formed by using epitaxial growth or epitaxial deposition processes. The process grows a monocrystalline semiconductor layer such as silicon (Si) or germanium (Ge). Although not shown in detail in FIG. 1A, a dielectric layer is provided between the gates 101a-d and both the source 102a-d and drain 103a-d regions. Therefore, the gates 101a-d are isolated from the source 102a-d and drain 103a-d regions by the dielectric layers.

The structure 100 also includes conductor layers 105a-d that are formed from conducting material such as metal. The conductor layers 105a-d are cut to form slits 109a-c to form power line or signal line patterns. For example, the cut conductor layers 105a-d can be used for power lines (VDD and VSS) or for signal lines. When used for power lines, the thickness of the conductor layers 105a-d can be increased to reduce the resistance. Because the conductor layers 105a-d are located under the transistors, the gates 101a-d and the source 102a-d and drain 103a-d regions can be directly connected to power lines or signal lines (e.g., conductor layers 105a-d) located underneath the gate, source, and drain regions.

The structure 100 also includes insulating layers 104 and 106. The insulating layers 104 and 106 are formed from material, such as oxide or nitride. For example, depending on the process technology, the insulting layer 106 may be an oxide substrate, or a berried oxide (BOX) layer on top of a silicon substrate, or an oxide layer inside a trench isolation in silicon substrate, or an insulating layer on back-end of line (BEOL) process.

The transistors of the structure 100 can be P-channel or N-channel devices. For metal gate technology, the control gates of PMOS and NMOS can have different metal material and structures. For example, the control gates 101a, 101d, and 101e for PMOS can be formed of WN/RuO2 (double-layer). The control gates 101b, 101c, and 101f for NMOS may be formed of Ta, TaN, or Nb.

Moreover, the transistors may be traditional junction devices, or junction-less devices. For traditional junction devices, the channels and the source/drain regions can have the opposite type of doping. For junction-less devices, the channels and the source/drain regions can have the same type of doping.

Logic gates such as invertors, NAND gates, or NOR gates are usually formed of pairs of PMOS and NMOS transistors. The transistors 101a and 101b can be PMOS transistors and the transistors 101c and 101d can be NMOS transistors. Large transistor arrays can be formed by duplicating the structure shown in FIG. 1A along X and Y array directions.

The various embodiments of the transistor structures have distinct advantages over conventional structures. First, the transistor size along the X-direction shown in FIG. 1A is only 2F (F is the feature size of the design rule), which results in much smaller transistor size compared with the conventional structure. Second, the process is fully self-aligned and it may only require two masks to define the transistors and gates. This significantly reduces the process cost. Third, by using a self-aligned contact process, the source and drain regions are directly connected to their respective power line below (or underneath) the transistor without adding extra contact process steps or layout size.

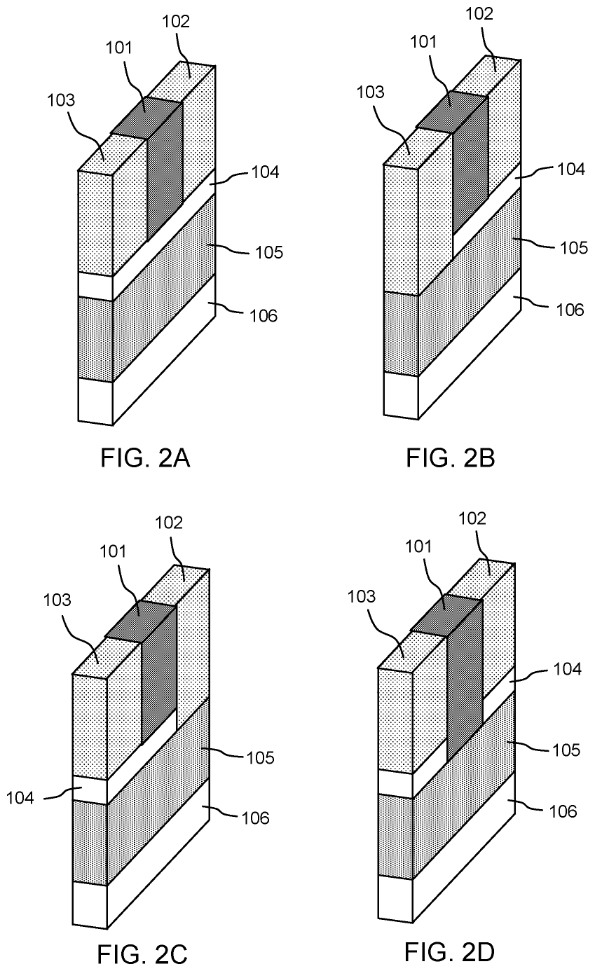

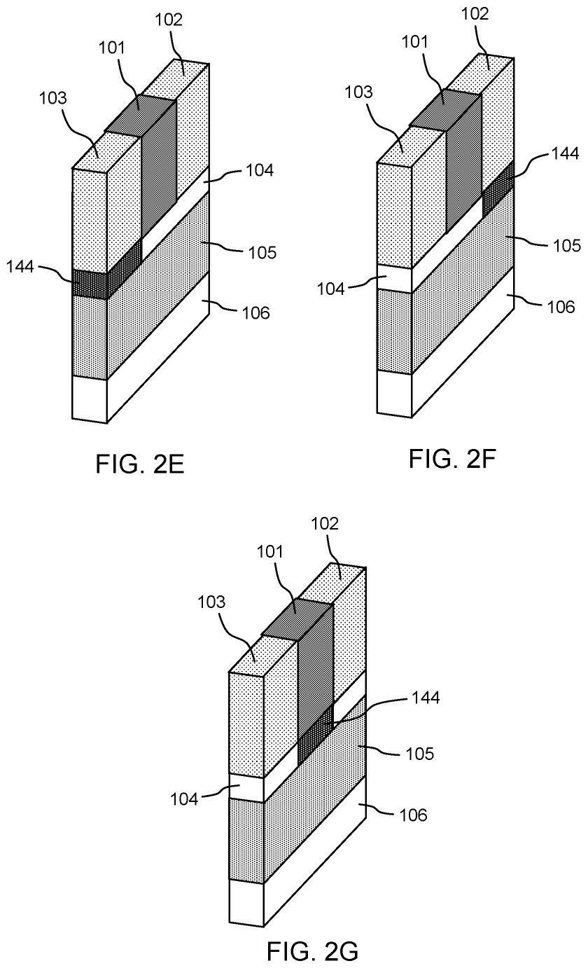

FIG. 1B shows another exemplary embodiment of a four lateral transistor structure 200 constructed according to the invention. The structure 200 is similar to the structure 100 shown in FIG. 1A except that the two power lines 105a-b are combined into power line 105a′ that is shared by two transistors 101a-b, and the two power lines 105c-d are combined into power line 105b′ that is shared by two transistors 101c-d. In an embodiment, the transistors 101a and 101b can be PMOS and the transistors 101c and 101d can be NMOS. The power lines 105a′ and 105b′ can be VDD and/or VSS bus lines, respectively. The gates, sources, and drains of the transistors 101a to 101d may be selected according to the circuit design to directly connect to the power lines 105a′ and 105b′, as illustrated in FIGS. 2A-G, which show additional embodiments of various types of power line connections.

FIG. 1C shows an exemplary embodiment of a transistor structure constructed according to the invention. This embodiment is similar to the embodiment shown in FIG. 1B except that eight lateral transistors 101a-h are shown. In an embodiment, the transistors 101a, 101b, 101e, and 101f are PMOS transistors. The transistors 101c, 101d, 101g, and 101h are NMOS transistors. The power lines 105a′ and 105c′ can be VDD buses, and the power lines 105b′ and 105d′ can be VSS buses.

FIG. 1D shows an embodiment of a transistor array structure 400 that comprise the transistor structure 100 shown in FIG. 1A. Multiple transistors are placed along X and Y directions to form a large array. The array structure 400 comprises control gates 101a-j, source regions 102a-j and drain regions 103a-j. The array structure 400 also comprises power lines 105a-e. The source and drain regions of each transistor are connected to the power line located below the transistor using a self-aligning contact process shown in FIGS. 4H-M. The control gates and source and drain regions are connected to metal layers on top of the transistors, for example, by using contacts, such as contacts 121a-c.

FIG. 1E shows another embodiment of a transistor array structure 500 that comprises the transistor structure 200 shown in FIG. 1B. The arrays structure 500 is similar to the array structure 400 shown in FIG. 1D except for the structure of the power lines 105a′, 105b′ and 105c′. In the array structure 500, each power line is shared by two lateral transistors.

FIGS. 2A-G show exemplary embodiments of transistor power line connections. Since the power line connections are underneath the lateral transistors, the structure of the power line connections shown in FIGS. 2A-G eliminate the extra layout size of power line contacts that are required by conventional transistors to connect the source to a power line located beside the transistor and therefore can achieve very compact layout size.

FIG. 2A shows a basic transistor structure without power line contacts. The transistor comprises a control gate 101, a drain region 102, a source region 103, an insulating layer 104, a conductor layer that is used for a power line 105, and an insulating layer 106. The gate 101, drain 102, and source 103 can be connected to metal layers on top of the transistor by using additional contacts (not shown). It should be noted that the insulator 104 prevents the gate 101, source 102, and drain 103 from contacting the power line 105.

FIG. 2B shows a transistor structure in which the source 103 is 6 directly connected (e.g., directly contacts) to the power line 105 by removing a portion of the insulating layer 104 under the source 103. This may be performed by a self-aligned etching process, which eliminates an extra contact process and layout area for connecting the source 103 to a metal contact on top of the source 103 and then connected to a power line located beside the transistor. Thus, it results in a more compact transistor size and reduces the manufacturing process cost. The process flow will be described below with reference to FIGS. 4A-L.

FIG. 2C shows a transistor structure in which the drain 102 is directly connected (e.g., directly contacts) to the power line 105 by removing the insulating layer 104 under the drain 102.

FIG. 2D shows a transistor structure in which the gate 101 is directly connected (e.g., directly contacts) to the power line 105 by removing the insulating layer 104 under the gate 101. This connection can be used to turn-off the gate 101 permanently to create a ‘dummy gate’.

FIGS. 2E-G shows additional exemplary embodiments of transistor structures constructed according to the invention. These embodiments are similar to the embodiments shown in FIGS. 2A-D except that contact 144 connects the power line 105 to the source 103 (FIG. 2E), drain 102 (FIG. 2F) and the gate 101 (FIG. 2G). The contact 144 is formed of a conductor layer, such as metal or polysilicon. The process steps performed to construct these embodiments are described with reference to FIG. 4G.

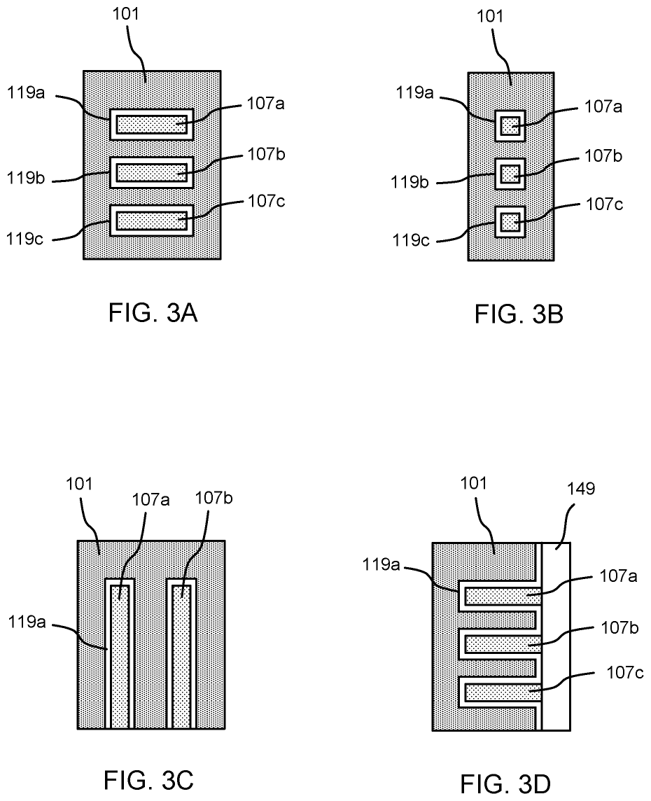

FIGS. 3A-D show additional exemplary embodiments of the gate 101 and the channel structure of the transistors constructed according to the invention. The transistor structures shown in FIGS. 3A-D comprise gate 101, channels 107a-c, gate dielectric layers 119a-c, and insulating layer 149. In various embodiments, the structures described herein can be implemented in many advanced transistor technologies, such as multi-bridge-channel field-effect transistor (MBCFET), as shown in FIG. 3A, gate-all-around field-effect transistor (GAAFET) or nanowire field-effect transistor (NWFET), as shown in FIG. 3B, FinFET, as shown in FIG. 3C, forksheet field-effect transistor, as shown in FIG. 3D, and any other suitable type of transistors structure.

FIGS. 4A-T show exemplary embodiments of process steps to form the transistor structure 200 shown in FIG. 1B.

FIG. 4A shows the results of a process step in which a structure is formed having a metal layer 105 for the power lines deposited on top of an insulating layer 106 such as oxide. An insulting layer 104, such as oxide, is deposited on top of the metal layer 105. Multiple semiconductor layers 107a-c and sacrificial layers 108a-d are alternately deposited on top of the insulating layer 104. In an embodiment, the semiconductor layers 107a-c are any semiconductor material suitable for forming channels of transistors, such as silicon (Si) or Germanium (Ge). In an embodiment, the sacrificial layers 108a-d are materials with different etching selectivity from the semiconductor layers 107a-c, such as silicon-germanium (SiGe), silicon-nitride (SiN), or any other suitable materials.

FIG. 4B shows the results of a process step in which the pattern of the gate are defined by lithography mask 100. The channel layers 107a-c and sacrificial layers 108a-d in the source 102 and drain 103 regions are etched using an anisotropic etching process, such as dry etch or deep trench process.

FIG. 4C shows the results of a process step in which the slits (or openings) in the source 102 and drain 103 regions are filled by sacrificial material (102′ and 103′), such as oxide or nitride.

FIG. 4D shows the results of a process step in which the pattern of the transistors are defined by lithography masks 110a-d to form the openings or slits 109a-c by using an anisotropic etching process, such as dry etch or deep trench process. As illustrated, the material 103′ is divided into 103′a-d by the slits 109a-c.

FIG. 4E shows the results of a process step in which the openings (or slits) 109a-c are filled with an insulator such as oxide or nitride. After that, the insulator in the slit 109b is patterned and selectively etched by using etching solution that only etches the insulator to reveal the opening or slit 109b as shown.

FIG. 4F shows the results of a process step in which the slit 109b is extended through the insulting layer 104 and the conductor layer 105 to form conductor lines 105a′ and 105b′ by using a self-aligned anisotropic etching process, such as dry etch.

FIG. 4G shows the results of a process step in which the slit 109b is filled with an insulator, such as oxide or nitride. The insulating layer 109b may have different etching selectivity from the insulating layers 109a and 109c. Therefore, the insulating layers 109a and 109c may be selectively etched without using a lithography mask, as illustrated in the process step shown in FIG. 4N.

FIG. 4H shows the results of a process step in which the power line contacts for source 102a-d and drain 103a-d regions are formed. For the regions that need to be connected to one of the power line 105a′ or 105b′, such as region 103d, the sacrificial layer material 103′d that was is the region 103d is patterned by a lithography mask and etched by using selective etching process, such as wet etch or dry etch.

FIG. 4I shows the results of a process step in which the insulating layer 104 in the area 111 at the bottom of the source region 103d is etched by using a self-aligned anisotropic etching process, such as dry etch, to expose the surface of the power line 105b′. For better etching control, the insulating layer 104 may have different etching selectivity from the insulating layers 109a-c. For example, the insulating layer 104 can be a nitride layer and the insulating layers 109a-c can be oxide layers. This allows the insulating layer 104 to be etched by using a self-align process using the insulating layer 109c as a mask.

FIG. 4J shows the results of a process step in which the sacrificial layers 102′a-d and 103′a-c in the source 102a-d and drain 103a-c regions are removed by using a selective etching process, such as wet etch or dry etch. In an embodiment, the insulating layers 109a-c have different etching selectivity from the sacrificial layers in the source 102a-d and drain 103a-c regions. Therefore, when the sacrificial layers are etched later by using a wet etching process, the insulators 109a-c will not be etched. A side view is also provided that illustrates the layers 107 and 108 after the source and drain regions are removed.

FIG. 4K shows the results of a process step in which the source 102a-d and drain 103a-d regions are filled by desired source and drain material, such as silicon (Si) or germanium (Ge). The source and drain layers may be formed by using epitaxial growth or epitaxial deposition processes. The process grows a monocrystalline semiconductor layer, such as silicon (Si) or germanium (Ge), in the holes of the source and drain regions. It should be noted that the source material in the source region 103d directly contacts with the power line 105b′ due to the insulating layer 104 in the area 111 being removed by etching, as shown in FIG. 4J. After the source 102a-d and drain 103a-d regions are formed, proper implantations and annealing may be applied to dope the source and drain regions. As illustrated in FIG. 4K, the source 103d directly contacts with the power line 105b′. A side view is also provided that illustrates the layers 107 and 108 and the added source 103d and drain 102d material.

FIGS. 4L-M show exemplary embodiments for using a conductor layer material, such as metal, to form the power line contacts.

FIG. 4L shows the results of a process step performed after the process step shown in FIG. 4I in which a contact layer 144 is deposited in the bottom area 111 of the source region 103d, and then pattern-etched by using a dry etch process to form the contact 144 in the selected source 103d. The thickness of the contact layer 144 can be adjusted by using an etch-back process. It should be noted that the process steps of ‘pattern-etching’ are well known in the semiconductor manufacturing process. The typical steps include deposition, photoresist coating, lithography exposure, photoresist pattern development, and anisotropic etching, such as dry etching or reactive-ion etching (RIE). For simplicity, the details of the pattern etching will not be repeated in the following description.

FIG. 4M shows the results of a process step performed after the contact 144 is formed. After the contact 144 is formed, the process shown in FIG. 4J is performed to remove the sacrificial layers in the source 102a-d and drain 103a-c regions. Then, the source 102a-c and drain 103a-c regions are formed by using epitaxial growth or epitaxial deposition processes to grow a monocrystalline semiconductor layer, such as silicon (Si) or germanium (Ge) in the holes of the source and drain regions, as shown in FIG. 4M.

FIG. 4N shows the results of a process step in which the insulating layers 109a and 109c are removed (to form slits) by using selective etching process, such as wet etch or dry etch. For example, this process step is performed after the process step shown in FIG. 4K. This produces channels that reveal the material 107a-c and the sacrificial layers 108a-d in the sidewalls of the slits 109a and 109c. The insulating layer 109b may have different selectivity for the etching solution than the layers 109a and 109c, thus the insulating layers 109a and 109c may be etched without using lithography masks.

FIG. 4O shows the results of a process step in which an isotropic etching process, such as wet etch, is performed to selectively etch the sacrificial layers 108a-d that are revealed by the slits 109a and 109c formed in the step shown in FIG. 4N. This reveals the surface of the channels material, such as material 107a-c. A side view is also provided that illustrates the channels 107a-c after the sacrificial layers 108a-d are removed.

FIG. 4P shows how a gate dielectric layer 119, such as high-K material hafnium oxide (Hf2O), is formed on the surface of the channel material 107a-c using thin-film deposition through the slits 109a and 109c. It should be noted that the gate dielectric layer also covers the surface of the exposed source 102a-c and drain 103a-d regions. Therefore, when the control gates are formed in the next process step shown in FIG. 4Q, the source 102 and drain 103 regions and the gates 101 are isolated.

FIG. 4Q shows the results of a process step in which the control gates 101a-d are formed to cover the channels 107a-c shown in FIG. 4O. To form the control gates 101a-d, the material of the control gate is deposited to cover the entire transistor structure, and then a photoresist layer of the gate pattern is formed by using a lithography step to define the gate pattern, and then etching the control gate material not being covered by the photoresist layer. The gates for PMOS transistors 101a and 101b and NMOS transistors 101c and 101d may be formed separately, if different metals are used for PMOS and NMOS. The slit 109a can be covered by a photoresist mask to perform the gate formation for the gates of NMOS 101c-d. Then, the slit 109c is covered by a photoresist mask to perform the gate formation for the gates of PMOS 101a-b.

FIG. 4R shows a side view of the structure shown in FIG. 4Q that illustrates the result of the deposition of the control gate 101d formed to cover the channels 107a-c. It should be noted that the gate 101a-d will not be shorted to the source 102a-d and drain 103a-d because the surfaces of the source 102a-d and drain 103a-d are covered by the gate dielectric layer 119.

In FIG. 4S, the gate dielectric layer 119 on top of source 102a-d and drain 103a-d can be selectively etched by using a solution that only etches the material of gate dielectric layer 119. The gate dielectric layer 119 covered by the control gate 101a-d will be protected by the control gate, thus it will not be etched. Therefore, this process step can be performed without using a mask.

After the gates are formed, the slits 109a and 109c may be filled with insulator such as oxide, as shown in FIG. 4T. As a result of the above-described processes, the transistor structure 200 shown in FIG. 1B is formed.

Many logic gates such as invertors, NAND gates, and NOR gates have ‘common gate’ structure, in which the gates for PMOS and NMOS transistors are connected together.

FIG. 4U shows the results of a process step in which a common gate structure is formed. In this process step, a conductor layer 150 comprising material such as metal is formed by using metal deposition and pattern-etching to connect the control gates of PMOS transistor 101b and NMOS transistor 101c.

FIGS. 4V-Y shows another exemplary embodiments of process steps using ‘metal-replacement’ technology in accordance with the invention. These process steps are suitable for metals that have lower melting temperatures, such as zinc and aluminum for example, which may not sustain the high temperature processes for forming the transistors, such as source and drain annealing. In these process steps, the power lines 105a′ and 105b′ are formed from a sacrificial material with high melting temperature first, and then replaced by metal later after the transistors are formed.

FIG. 4V shows the results of a process step similar to the previous embodiment shown in FIG. 4O, except that the layers 105a′ and 105b′ can be sacrificial layers with higher melting temperatures, such as nitride. The insulating layer 104 in the areas 151a and 151b are etched by using a selectively anisotropic etching process through the slits 109a and 109c to expose the sacrificial layers 105a′ and 105b′.

FIG. 4W shows the results of a process step in which an isotropic etching process, such as wet etch, is performed through the slits 109a and 109b to selectively etch the sacrificial layers 105a′ and 105b′.

FIG. 4X shows the results of a process step in which the metal for the power lines is deposited through the slits 109a and 109c to fill the space of 105a′ and 105b′. An etch-back process may be performed after the metal deposition to precisely control the thickness of the metal lines 105a′ and 105b′.

FIG. 4Y shows the results of a process step in which an insulator as oxide may be deposited in the slits 109a and 109c, and etched back to form the insulating layers 152a and 152b. As a result, the power lines 105a′ and 105b′ are replaced by the desired metal. After that, the process step shown in FIG. 4P may be performed to form the control gates 101a-d of the transistors.

In another embodiment, the metal-replacement process is performed after the process step shown in FIG. 4Q. The process steps are similar to the one shown in FIGS. 4V-Y, except that before the process step shown in FIG. 4V, a thin film of insulating layer is deposited in the sidewall surface of the slits 109a and 109c. This prevents the metal gates 101a-d from being affected by the metal deposition and etch-back process for the power lines 105a′ and 105b′.

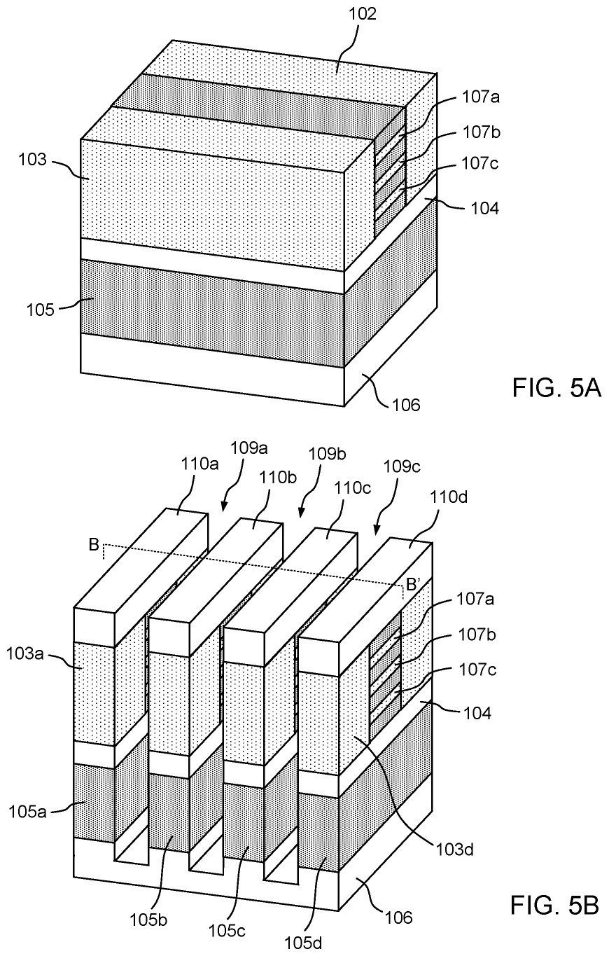

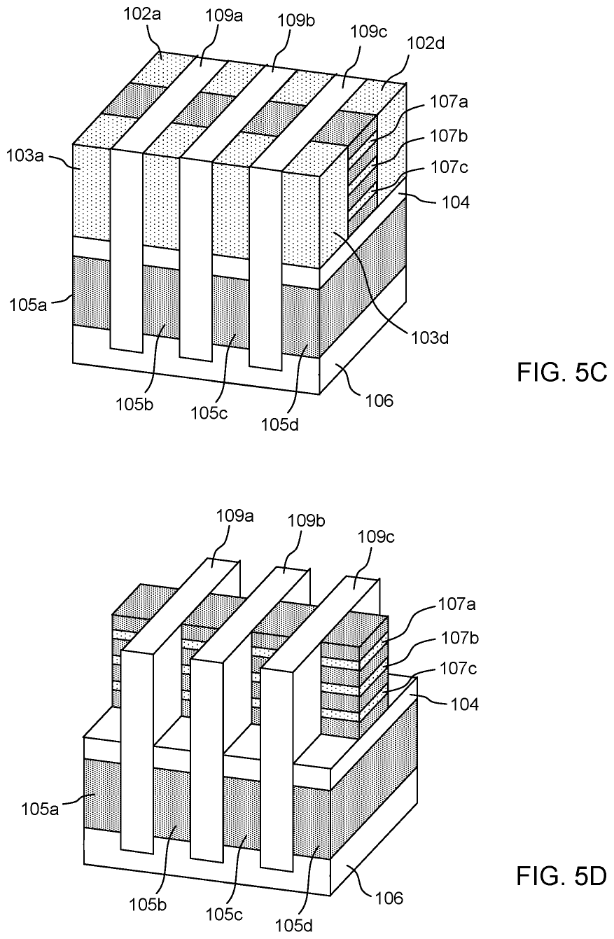

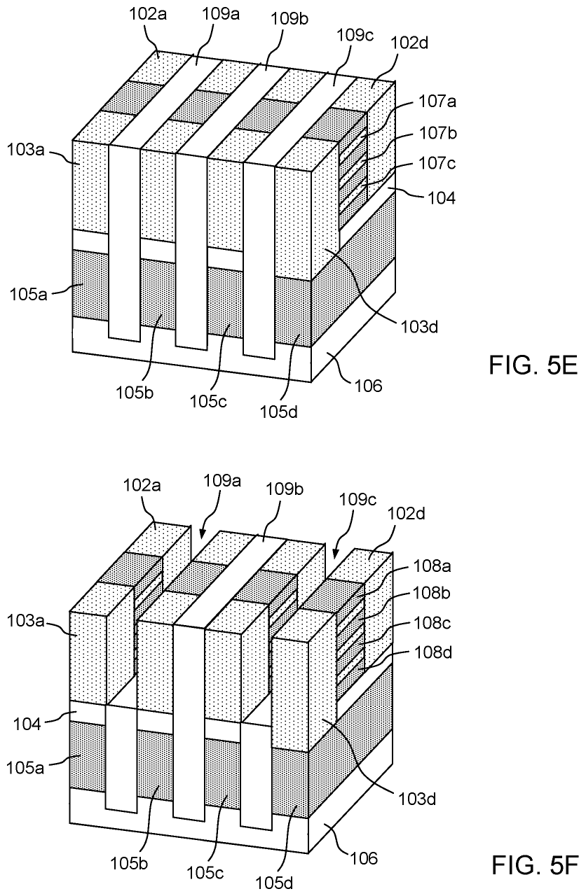

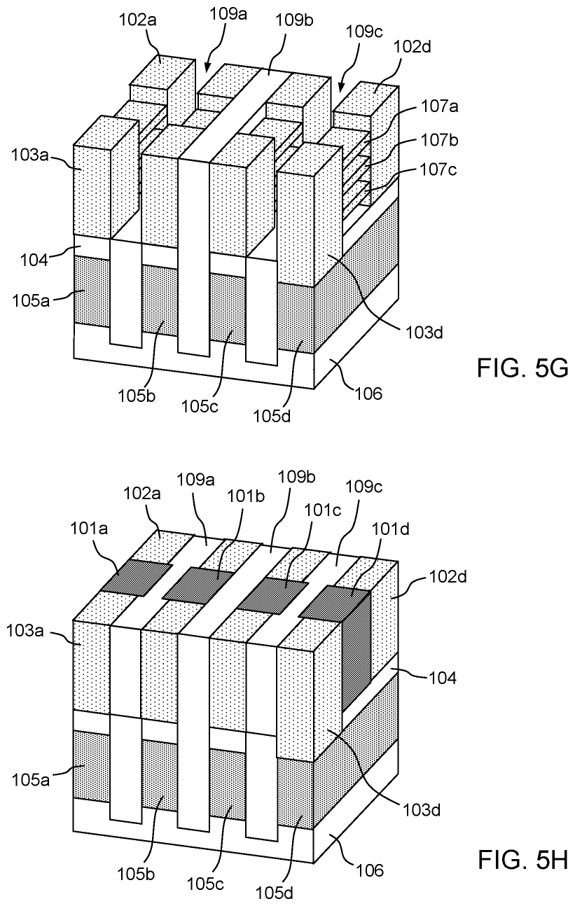

FIGS. 5A-H show exemplary embodiments of process steps used to form the transistor structure shown in FIG. 1A in accordance with the invention. These embodiments are similar to the ones shown in FIGS. 4A-Q except that as shown in FIG. 5B, the slits 109a and 109c are extended like 109b to cut the metal layer under the transistors into metal lines 105a to 105d.

FIGS. 5A-H shows the transistor structures after the process step shown in FIGS. 4C-Q, respectively. For clarity and simplicity, the detailed descriptions for these process steps are not repeated here, but can be found in the detailed descriptions of FIGS. 4A-Q above.

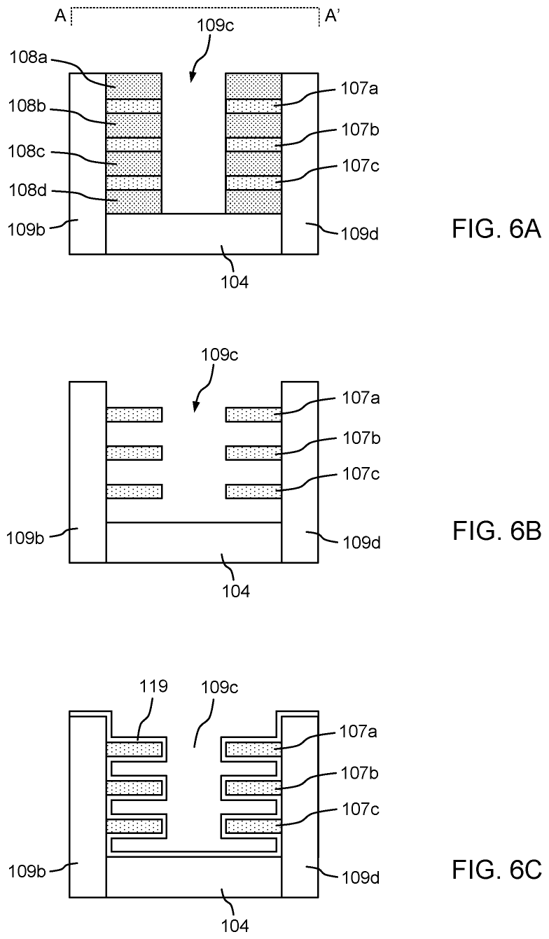

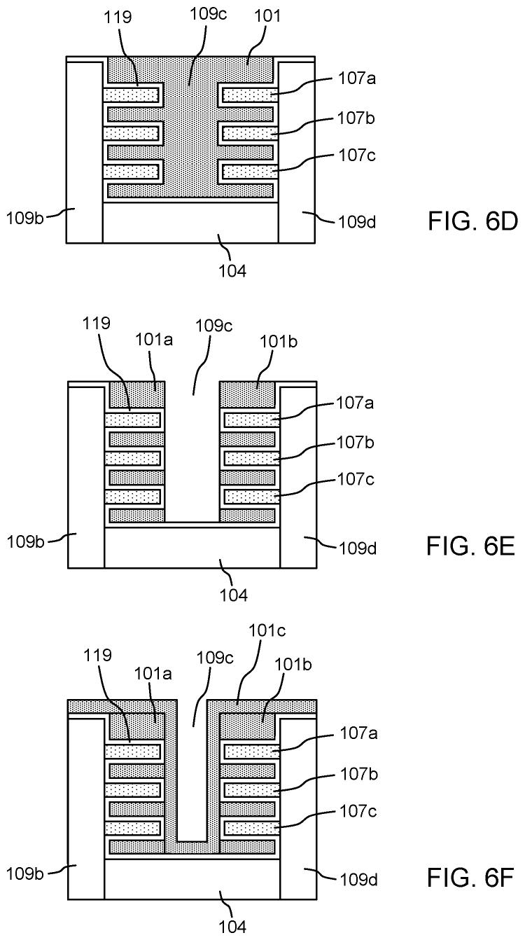

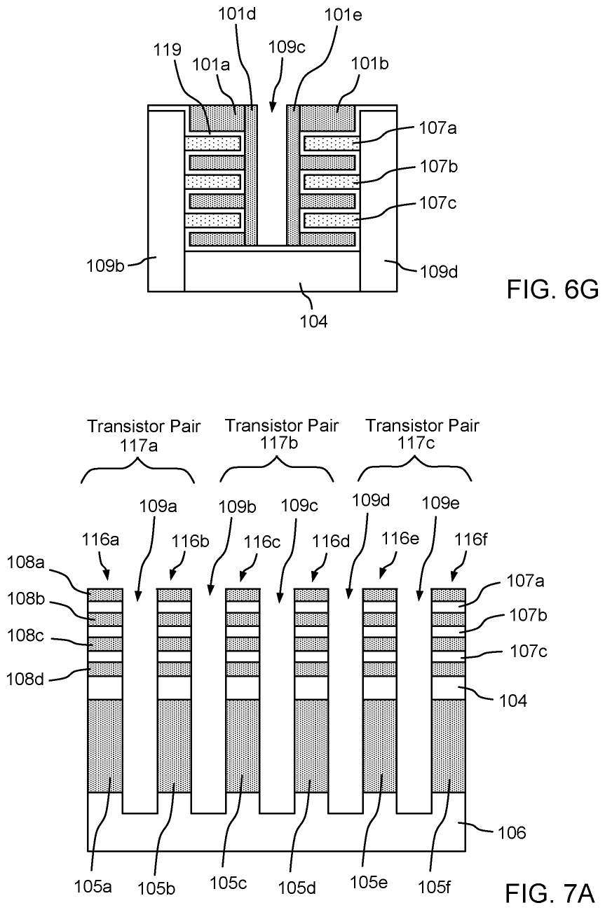

FIGS. 6A-G shows exemplary detailed process steps for forming the channels and the gates of the transistor structure as described with respect to FIGS. 4N-P.

FIG. 6A shows a cross-section view along the cross-section indicator (A-A′) in the X direction after the process step shown in FIG. 4N. For clarity, an insulating layer 109d is added to the structure shown in FIG. 6A but this layer is not shown in FIG. 4N. The structure shown in FIG. 6A includes the slit 109c, insulating layers 109b and 109d, and channel layers 107a-c. Also shown are sacrificial layers 108a-d and an insulating layer 104 under the transistor. The conductor layer 105b′ is not shown in FIG. 6A.

FIG. 6B shows the results of a process step in which the sacrificial layers 108a-dare selectively etched by using an isotropic process, such as wet etch through the slit 109c.

FIG. 6C shows the results of a process step in which a gate dielectric layer 119, such as high-K material hafnium oxide (Hf2O) is formed on the surface of the channels 107a-c by using a thin-film deposition process through the slit 109c.

FIG. 6D shows the results of a process step in which a control gate material 101, such as metal, is deposited to fill the slit 109c and the space between the channels 107a-c as shown.

FIG. 6E shows the results of a process step in which an anisotropic etching process, such as dry etch, is performed to etch the control gate material 101 in the slit 109c to form the residuals of the control gate layers 101a-b between the channel layers 107a-c.

FIG. 6F shows the results of a process step in which a control gate layer 101c is formed on the surface of the structure shown in FIG. 6E by using thin-film deposition. In an embodiment, the material of the control gate layer 101c may be the same as the material of the control gate layers 101a-b. Therefore, the control gate layer 101c connects all the control gate layers between the channel layers 107a-c.

FIG. 6G shows the results of a process step in which an etch-back process is performed without using a mask to etch the control gate layer 101c on the top of the structure and in the bottom of the slit 109c. This forms the control gate sidewall spacers 101d and 101e. As a result, two individual control gates are formed. The first control gate contains 101a and 101d. The second control gate contains 101b and 101e.

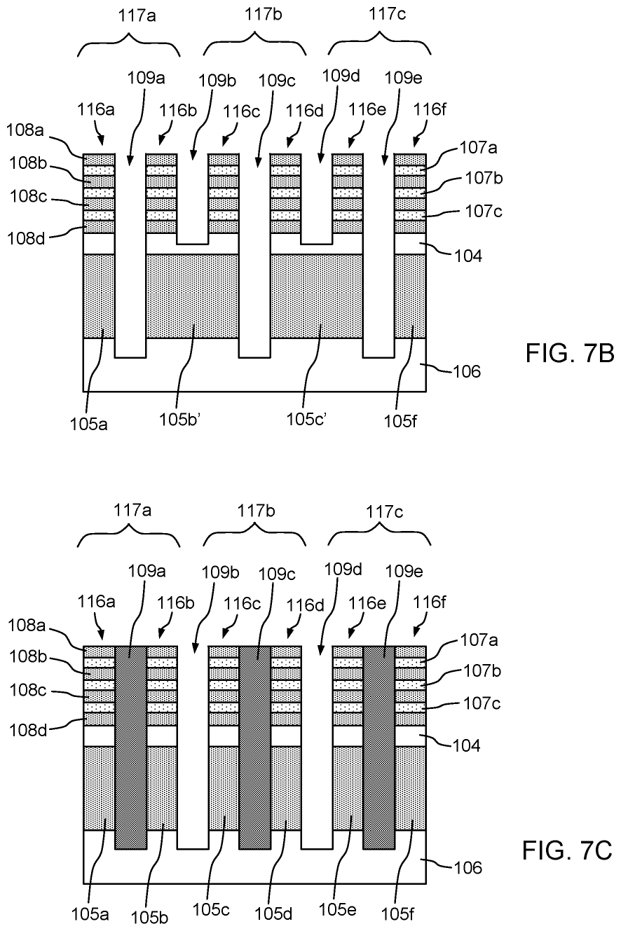

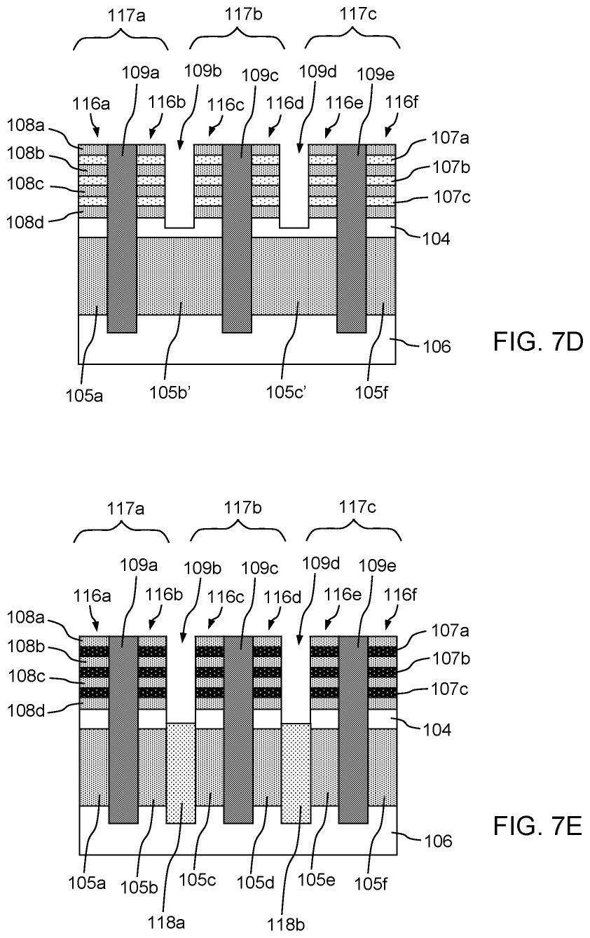

FIGS. 7A-E shows exemplary embodiments of a transistor structure according to the invention. For example, FIGS. 7A-E show cross-section views of the transistor structure shown in FIG. 5B taken along the cross-section indicator (B-B′). For clarity, the masks 110a-d are not shown and the structure shown in FIG. 5B is extended to shown six transistors (116a-f).

FIG. 7A illustrates how the structure can be divided into three pairs of PMOS and NMOS transistors 117a-c. In an embodiment, the transistors 116a, 116d, and 116e are PMOS transistors and the transistors 116b, 116c, and 116f are NMOS transistors. The power lines 105a, 105d, and 105e below the PMOS transistors form a VDD bus and the power lines below the NMOS transistors 105b, 105c, and 105f form a VSS bus.

FIG. 7B shows an exemplary embodiment of a transistor structure according to the invention. This embodiment is similar to the embodiment shown in FIG. 7A except that the slits 109b and 109d are not etched through to the metal layers 105b′ and 105c′. This results in wider power lines. However, it uses additional masks for the shallower slits 109b and 109d. The power lines 105a and 105c′ are connected to VDD bus and the power lines 105b′ and 105f are connected to VSS bus.

FIG. 7C shows an exemplary embodiment of a transistor structure according to the invention. This embodiment is similar to the embodiment shown in FIG. 7A except that after the slits 109a-e are formed, the slits 109a, 109c, and 109e are filled with an insulator, such as oxide or nitride. Then, the NMOS transistors 116b and 116c are formed through the slit 109b. The PMOS transistors 116d and 116e are formed though the slit 109d.

FIG. 7D shows an exemplary embodiment of a transistor structure according to the invention. This embodiment is similar to the embodiment shown in FIG. 7C except that the slits 109b and 109d do not etch through the metal layers 105b′ and 105c′. This results in wider power lines. However, it utilizes additional masks for the shallower slits 109b and 109d. The power lines 105a and 105c′ are connected to VDD bus and the power lines 105b′ and 105d are connected to VSS bus.

FIG. 7E shows an exemplary embodiment of a transistor structure according to the invention. This embodiment is similar to the embodiment shown in FIG. 7C except that the slits 109b and 109d are filled with conductor such as metal. The metal is etched back to form the metal lines 118a and 118b. In an embodiment, the material of the metal lines 118a and 118b and the power lines 105a-f may be the same. This structure can increase the width of the power lines. The power lines 105b, 105c, and 118a can be connected to VSS bus. The power lines 105d, 105e, and 118b can be connected to VDD bus.

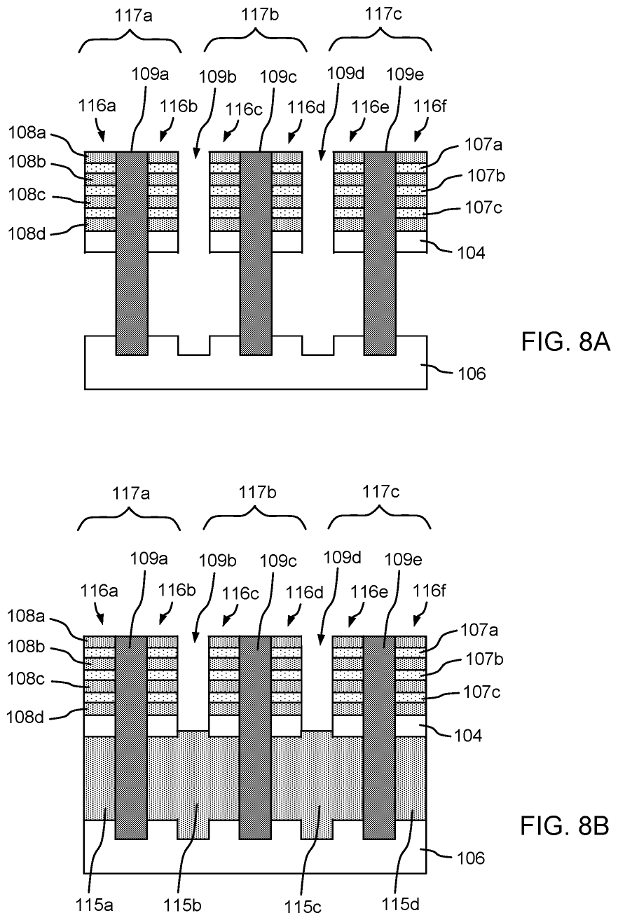

FIGS. 8A-B show exemplary embodiments of a transistor structure constructed according to the invention. These embodiments are similar to the one shown in FIG. 7C except that the power lines 105a-f are formed of sacrificial layer such as nitride. After the structure shown in FIG. 7C is formed, the power lines 105a-f are selectively etched by using an isotropic etching process, such as wet etch, to form the structure shown in FIG. 8A.

FIG. 8B shows the results of a process step in which the slits 109b and 109d are filled with conductor material, such as metal. Next, the metal is etched back to form the power lines 115a-d.

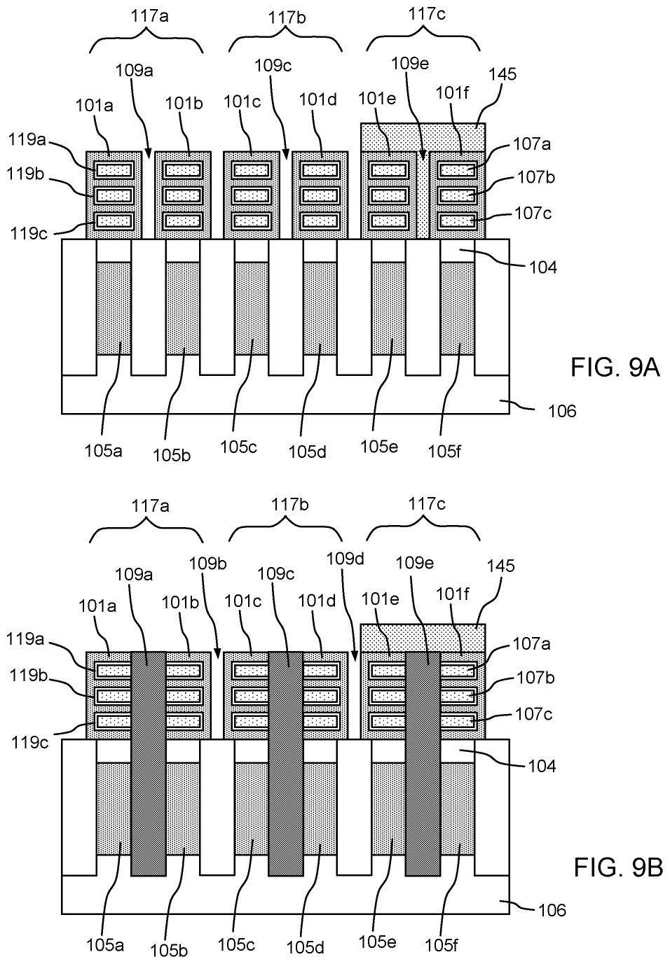

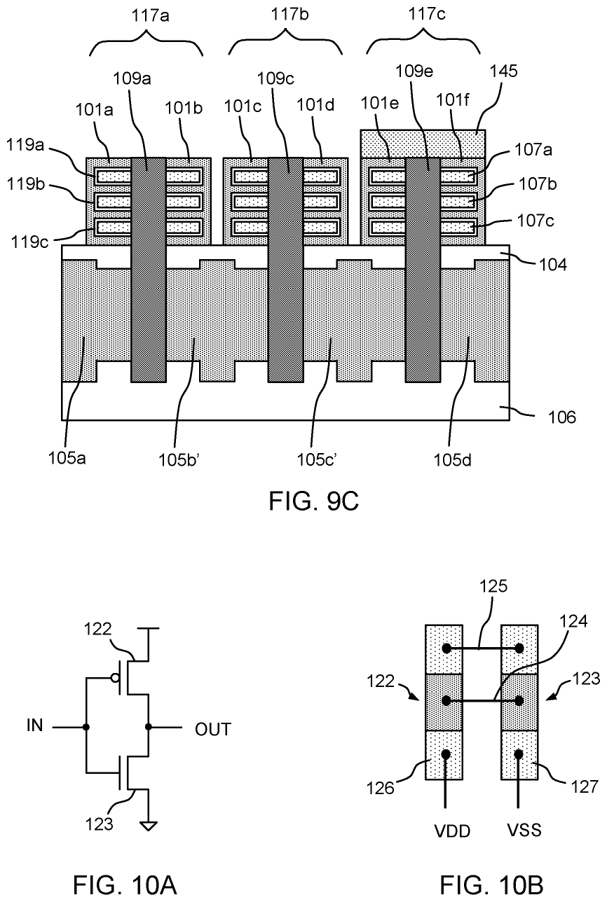

FIG. 9A shows an exemplary embodiment of a transistor structure constructed according to the invention. This embodiment shows the complete transistor structure for the embodiment shown in FIG. 7A after the gate dielectric layers 119a-c and the control gates 101aa -f are formed. The process steps for forming the gate dielectric layers and control gates are described with reference to FIGS. 6A-G.

It should be noted that depending on the technology, PMOS and NMOS transistors could have different types of metal gate materials. For example, the gates 101a, 101d, and 101e for PMOS could be formed of WN/RuO2 (double-layer). The gates 101b, 101c, and 101f for NMOS could be formed of Ta, TaN, or Nb.

For many logic gates such as invertor, NAND gate, NOR gate, etc. the gates of a PMOS such as 101e and a NMOS such as 101f are connected, called ‘common gate’. For this structure, a conductor layer 145 such as metal or polysilicon can be deposited and pattern-etched to form the common gate.

FIG. 9B shows an exemplary embodiment of a transistor structure constructed according to the invention. This embodiment shows the complete transistor structure for the embodiment shown in FIG. 7C after the gate dielectric layers 119a-c and the control gates 101a-f are formed. The process steps for forming the gate dielectric layers and control gates are described with reference to FIGS. 6A-G except that the processes are performed through the slits in one side instead of two sides. For example, the slits 109a, 109c, and 109e between PMOS and NMOS transistors are filled with an insulator first. Then, the process for forming the NMOS gates 101b and 101c are performed through the slit 109b, and the process for forming the PMOS gates 101d and 101e are performed through the slit 109d.

Similar to FIG. 9A, depending on the technology, PMOS and NMOS transistors shown in FIG. 9B can have different types of metal gate materials. For example, the gates 101a, 101d, and 101e for PMOS can be formed of WN/RuO2 (double-layer). The gates 101b, 101c, and 101f for NMOS can be formed of Ta, TaN, or Nb. For common gates, a conductor layer 145, such as metal or polysilicon, can be deposited and pattern-etched to form the common gate.

FIG. 9C shows an exemplary embodiment of a transistor structure constructed according to the invention. This embodiment shows the complete transistor structure for the embodiment shown in FIG. 8B after the gate dielectric layers 119a-c and the control gates 101a-f are formed. This embodiment is similar to the one shown in FIG. 9B except that the power lines 105a-d are formed by using a metal-replacement process. A description of the metal-replacement process is provided with reference to FIGS. 8A-B.

In various exemplary embodiments described herein, the processes, methods steps, and flows are exemplary and may be modified, added to, simplified, or changed within the scope of the invention.

FIGS. 10A-B shows exemplary embodiments of an inverter circuit constructed using embodiments of the transistor structure described herein.

FIG. 10A shows an inverter circuit that comprises a PMOS transistor 122 and an NMOS transistor 123.

FIG. 10B shows a top view of a layout of the inverter circuit shown in FIG. 10a that uses an embodiment of the transistor structure disclosed herein. As illustrated in the layout, the PMOS transistor 122 and the NMOS transistor 123 are shown. An input 124 is connected to the gates of the PMOS 122 and NMOS 123 transistors. An output 125 is connected to drains of the PMOS 122 and NMOS 123 transistors. The sources 126 and 127 of the transistors are connected to VDD and VSS power lines that are located under the PMOS 122 and NMOS 123 transistors and are not visible in this top view. Since the VDD and VSS power lines are located under the PMOS 122 and NMOS 123 transistors, the layout size is much smaller than a layout using conventional transistor structures.

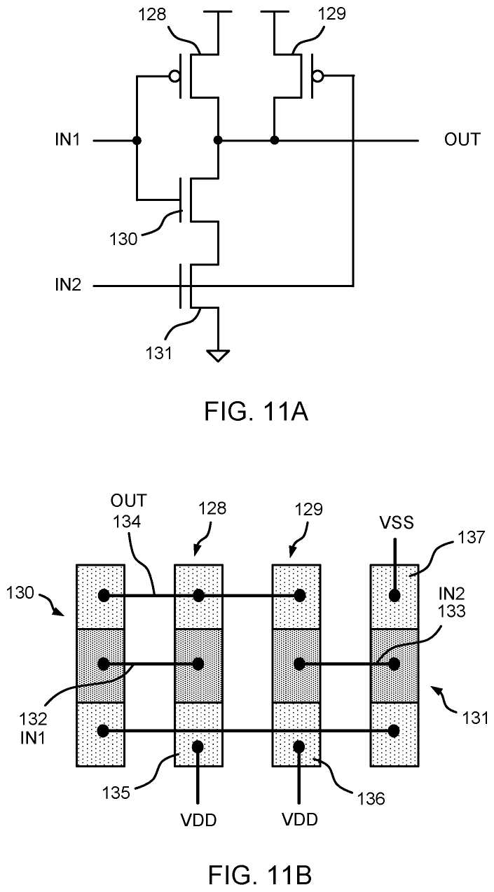

FIGS. 11A-B show embodiments of a NAND logic gate using embodiments of the transistor structure describe herein.

FIG. 11A shows a NAND gate circuit comprising two PMOS transistors (128, 129) and two NMOS transistors (130 and 131) constructed in accordance with the invention. The NAND gate circuit includes two inputs (IN1 and IN2) and one output (OUT).

FIG. 11B shows a top view layout of the NAND gate circuit shown in FIG. 11A. The layout comprises the PMOS transistors (128 and 129) and the NMOS transistors (130 and 131). The layout illustrates how the first input (IN1) 132 is connected to the gates of PMOS 128 and NMOS 130. The second input (IN2) 133 is connected to the gates of PMOS 129 and NMOS 131. The output (OUT) 134 is connected to the drains of PMOS 128, PMOS 129, and NMOS 130. The sources (135 and 136) of the transistors (128 and 129) are connected to VDD power lines that are located under the PMOS transistors (128 and 129), respectively. The source 137 of transistor 131 is connected to VSS power lines located under the NMOS transistor 131. Since the power line connections can be made under the transistor devices, the layout size is much smaller than a layout using a conventional transistor structure.

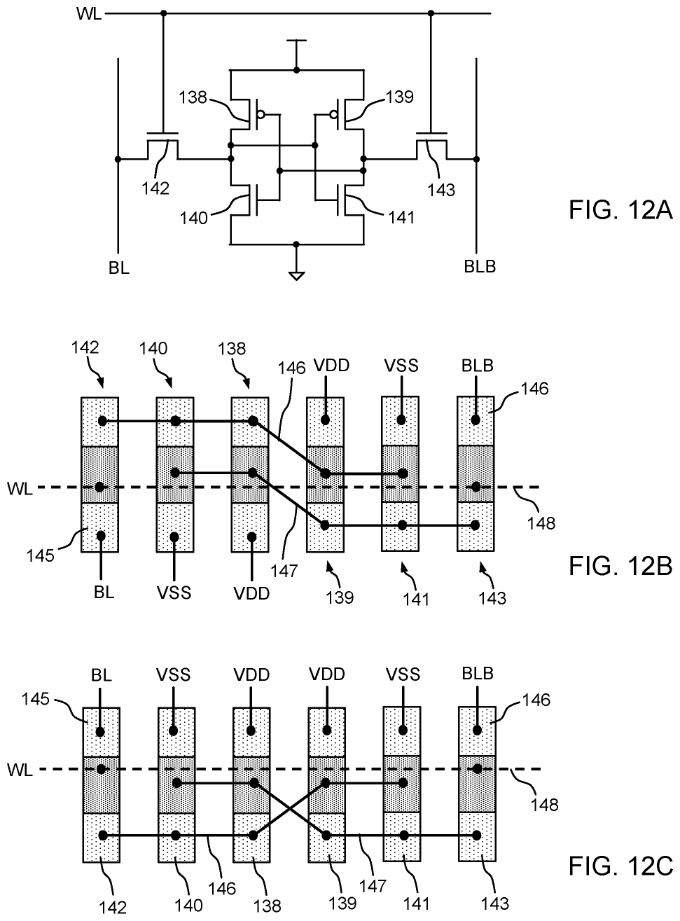

FIGS. 12A-C show embodiments of a static random-access memory (SRAM) cell constructed using the transistor structure described herein in accordance with the invention.

FIG. 12A shows an exemplary SRAM circuit that comprises a latch formed of two PMOS transistors (138, 139) and two NMOS transistors (140, 141), and two NMOS select transistors (142, 143).

FIG. 12B shows an exemplary top view layout of the SRAM cell shown in FIG. 12A that comprises two PMOS transistors (138, 129) and four NMOS transistors (140, 141, 142, and 143). The layout includes first metal (M1) layer connection 146 and 147 and a second metal (M2) layer connection 148. The sources of the PMOS transistors (138 and 139) are connected to a VDD bus that is located under the transistors. The sources of the NMOS transistors (140 and 141) are connected to a VSS bus that is located under the transistors. The source 145 of the NMOS transistor 142 and the source 146 of the NMOS transistor 143 are connected to bit line (BL) and bit line bar (BLB) signals, respectively. The BL and BLB can be formed of the metal lines under the transistors, or can be formed on the first metal (M1) layer on top of the transistors.

FIG. 12C shows another embodiment of the layout of the SRAM cell. As can be seen from the various embodiments, the SRAM cell using the transistor structure disclosed herein provides several advantages including extra compact layout size.

The previous embodiments shown in FIG. 1A to FIG. 12C use a ‘self-aligned’ process to form the power line pattern, such as power lines 105a-d shown in FIG. 1A. The power lines are defined by the same photoresist mask of the transistors. Therefore, additional masks are not used to define the power line pattern. This reduces the number of process steps and manufacturing cost and minimizes the device size by eliminating the misalignment between masks.

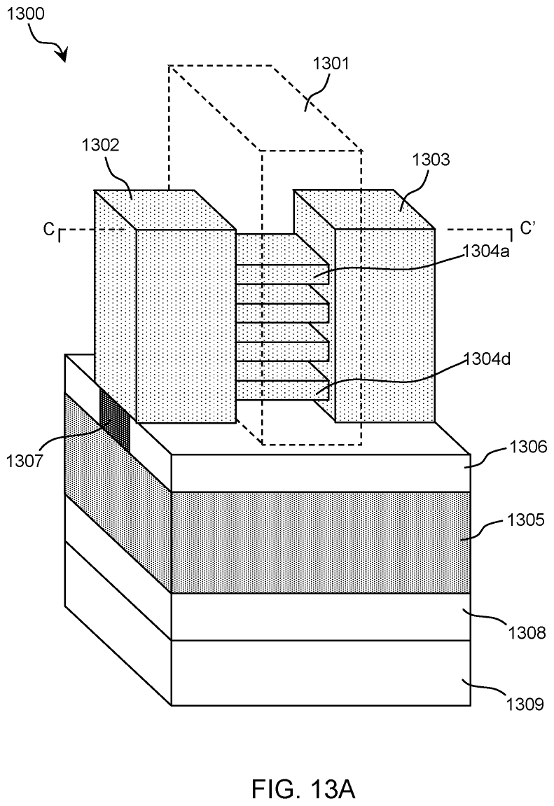

FIG. 13A to FIG. 17 shows additional exemplary embodiments of transistor structures constructed according to the invention using a ‘non-self-aligned’ process. In these embodiments, the patterns of the power lines and the transistors are formed separately.

FIG. 13A shows an exemplary embodiment of a transistor device 1300 constructed according to the invention. The device 1300 comprises a control gate 1301, which is formed of a conductor material, such as metal or polysilicon. The gate 1301 is shown by dashed lines to reveal the structure of multiple channels 1304a-d within the control gate 1301. In this embodiment, MBCFET technology is used as an example. In accordance with the invention, the transistor device 1300 may comprise MBCFET, GAAFET, NWFET, and any other type of applicable transistor technology.

The channels 1304a-d are formed from semiconductor material, such as silicon (Si), germanium (Ge), or other suitable material. In an embodiment, the channels 1304a-d are formed by using epitaxial thin-film deposition to grow a thin layer of monocrystalline semiconductor, such as silicon. The surface of the channels 1304a-d can be covered by a gate dielectric layer, such as thin oxide or Hi-K material, such as HfO2 or other suitable material. When the control gate 1301 is supplied with a voltage higher than the threshold voltage (Vt) of the channels 1304a-d, the channels will be turned on to conduct current.

The device 1300 also comprises source 1302 and drain 1303 regions. In an embodiment, the source 1302 and drain 1303 regions are formed by epitaxy, which is also called epitaxial growth or epitaxial deposition process. The process grows a monocrystalline semiconductor layer, such as silicon or germanium. The source 1302 and drain 1303 regions are connected to the channels 1304a-d. When the channels 1304a-d are turned on, current may flow between the source 1302 and drain 1303 regions. When the channels 1304a-d are turned off, the source 1302 and drain 1303 regions will remain isolated.

The device 1300 also comprises a power line 1305, which is formed from conductor material, such as metal or polysilicon. The power line 1305 is connected to power (VDD) or ground (VSS), depending on the desired circuit design. An insulating layer 1306, such as oxide, is also provided. The power line 1305 connects to the source region 1302 through a contact 1307. The contact 1307 is formed from a conductor material, such as metal. In an embodiment, the metals of the power line 1305 and the contact 1307 have a high melting temperature, such as tungsten (W), in order to sustain the high-temperature process steps of forming the transistor 1300.

In various embodiments, the transistor device 1300 may be a P-channel or N-channel device. Moreover, the transistor 1300 may be a traditional junction device, or a junction-less device. For traditional junction device, for P-channel device, the channels 1304a-d may have N-type of doping, and the source 1302 and drain 1303 may have P-type of doping. For N-channel device, the channels 1304a-d may have N-type of doping and the source 1302 and drain 1303 may have N-type of doping. For junction-less devices, the doping type of the channels 1304a-d is the same as the doping of the source 1302 and drain 1303.

In conventional logic gate design, the P-channel device's source 1302 may be connected to VDD, and N-channel device's source 1302 may be connected to VSS.

However, in the device structure shown in FIG. 13A, the power line 1305 is located under the transistor device. This structure is called Tower-Under-Device (PUD)' or ‘Device-Over-Power (DOP)’ in accordance with the invention. This structure significantly reduces the silicon area of the device. In contrast, the conventional transistor device's power lines are located on the side of the device and therefore, the power lines occupy considerable silicon area.

Depending on the process technology, the device 1300 may be located in different layers or materials. For example, if a standard semiconductor (such as silicon) wafer is used, the device 1300 may be located on top of the semiconductor substrate 1309 such as silicon. An insulating layer 1308, such as oxide, can be formed on top of the substrate 1309, and then the power line 1505 is formed on top of the insulting layer 1308.

In another process, the insulting layer 1308 is formed by using a shallow trench isolation (STI) process to form trenches on the surface of the substrate 1309 and these trenches are filled with an insulator such as oxide. Then, the power line 1305 is formed on the insulating layer 1308. In another process using Silicon-On-insulator (SOI), the insulating layer 1308, such as oxide, is formed in the surface of the substrate 1309. In another process using three-dimensional (3D) integration, the device 1300 is located in the layers of back-end-of-line (BEOL). The power line 1305 is located on top of the insulating layer on top of other circuits.

FIG. 13B shows an embodiment of a vertical cross-section view along cross-section indicator (C-C′) shown in FIG. 13A to reveal the structure of the contact 1307. In one embodiment, the contact is formed by conductor material, such as metal. The metal may have a high melting temperature, such as tungsten (W), to withstand subsequent high-temperature process steps.

FIG. 13C shows another embodiment of the vertical cross-section view along cross-section indicator (C-C′) shown in FIG. 13A to reveal the structure of the contact 1307. In this embodiment, the contact 1307 is formed by the same material and process as the source region 1302, such as monocrystalline silicon formed by using epitaxial growth/deposition process.

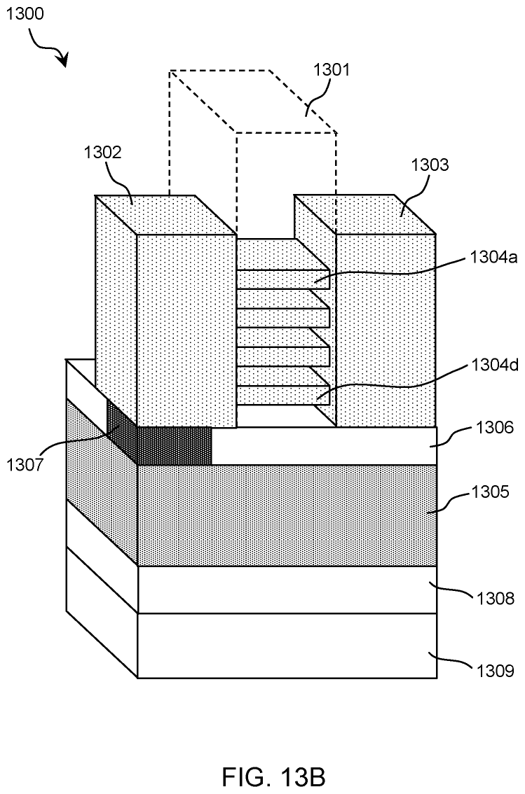

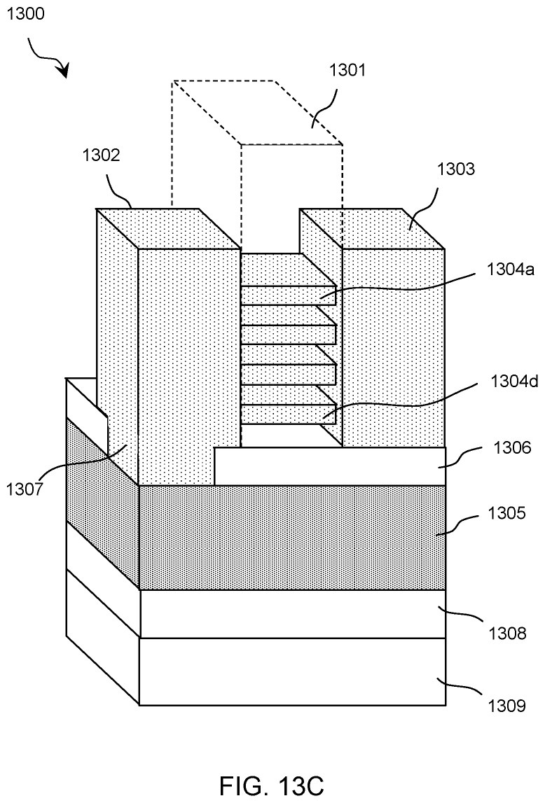

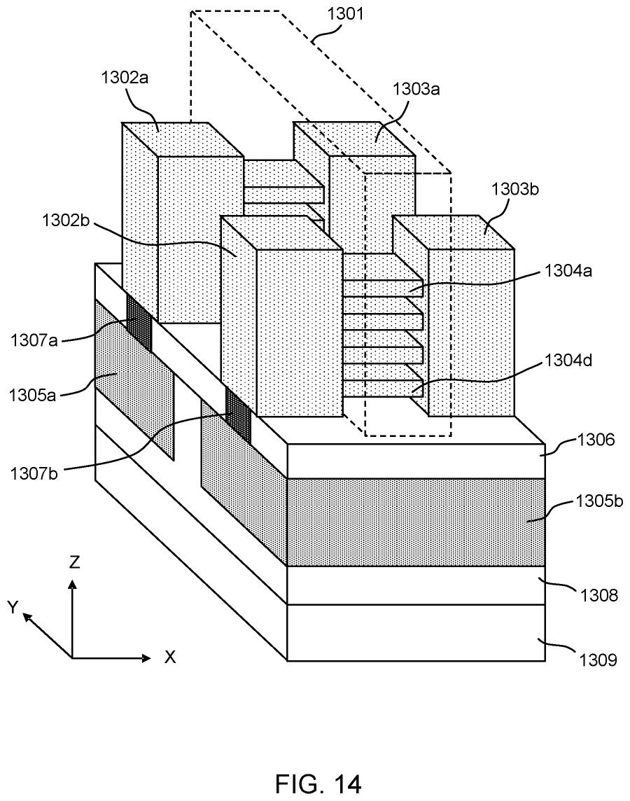

FIG. 14 shows an exemplary embodiment of a structure providing two complementary transistors according to the invention. The first transistor has source 1302a and drain 1303a is a P-channel device, and the second transistor has source 1302b and drain 1303b is an N-channel device. The control gate 1301 of the two transistors is connected as shown to connect the two transistors together. In another embodiment, the control gate 1301 is connected separately to each transistor according to the requirements of the circuit.

The complementary transistors form the basic structure for logic gates, such as invertors, NAND gates, NOR gates, XOR gates, and so on. The logic gates can be used to build circuits such as flip-flops, latches, combination logic, and so on.

The structure includes power lines 1305a and 1305b. In accordance with the invention, the power lines 1305a and 1305b are located under the P-channel device and the N-channel device, respectively, to reduce the silicon area. The power lines 1305a and 1305b may be connected to VDD and VSS, respectively, and further connected to the source regions 1302a and 1302b through the contacts 1307a and 1307b, respectively. The drain regions 1303a and 1303b may be connected to other devices, according to the structure of the desired logic gate that is formed from the devices. For example, if the desired logic gate is an inverter, the drain regions 1303a and 1303b are connected together to form the output of the inverter.

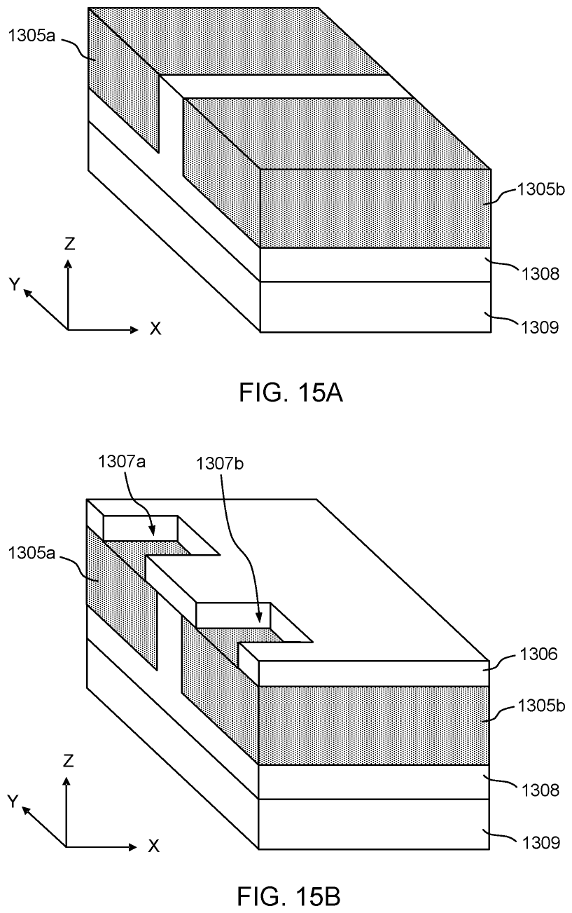

FIG. 15A shows an exemplary structure of the power lines 1305a and 1305b. In FIG. 15A, the layers above the power lines 1305a and 1305b are removed to reveal the structure of the power lines. The power lines 1305a and 1305b formed of conductor material may be extended in the X-direction, and connected to the sources of the transistors of a plurality of logic gates.

FIG. 15B shows an exemplary structure of the power lines 1305a and 1305b and the contact holes (openings) 1307a and 1307b. In an embodiment, the contact holes 1307a and 1307b are formed by pattern-etching on the insulating layer 1306, according to the structure of the desired logic gates. In an embodiment, the contact holes 1307a and 1307b are filled with contact material to form the structure shown in FIG. 2E.

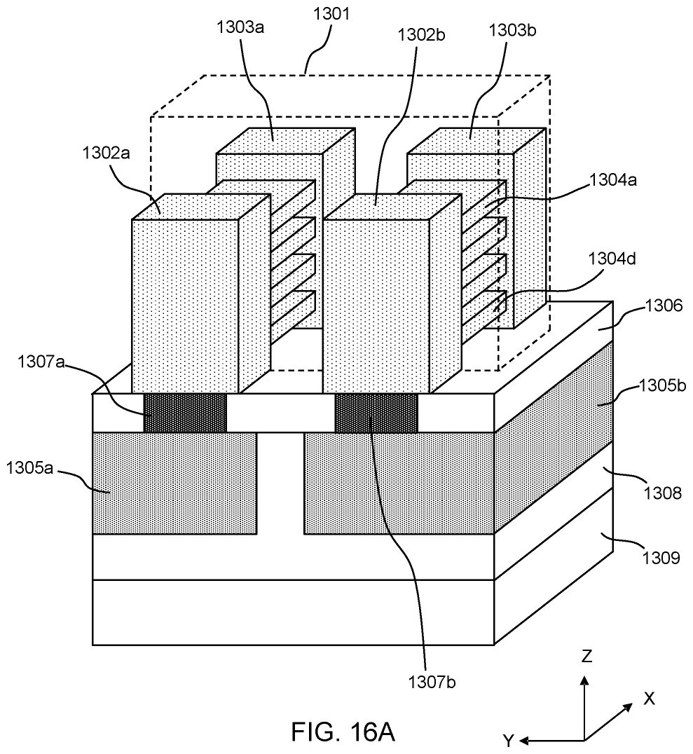

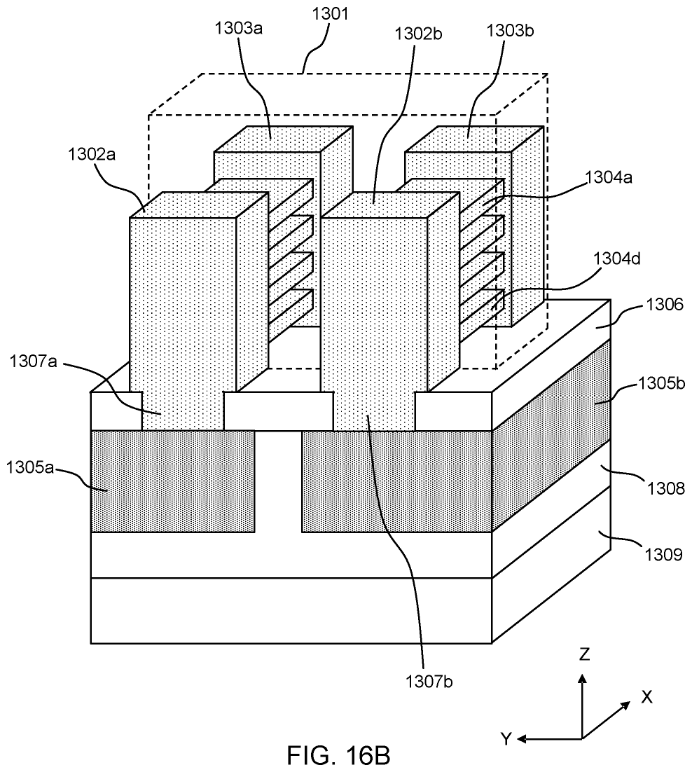

FIG. 16A shows a Y-direction view of the transistor structure shown in FIG. 14. As shown in FIG. 16A, the source regions 1302a and 1302b of the P-channel device and N-channel device are connected to the power lines 1305a and 1305b through the contacts 1307a and 1307b, respectively. The power lines 1305a and 1305b may be connected to VDD and VSS, respectively. In this embodiment, the contacts 1307a and 1307b may be formed from conductive material, such metal.

FIG. 16B shows an exemplary embodiment of the transistor structure shown in FIG. 16A. This embodiment is similar to the embodiment shown in FIG. 4A except that the contacts 1307a and 1307b are formed of the same material as the source regions 1302a and 1302b. For example, the contacts 1307a and 1307b are formed by using an epitaxial process to grow a semiconductor layer, such as silicon.

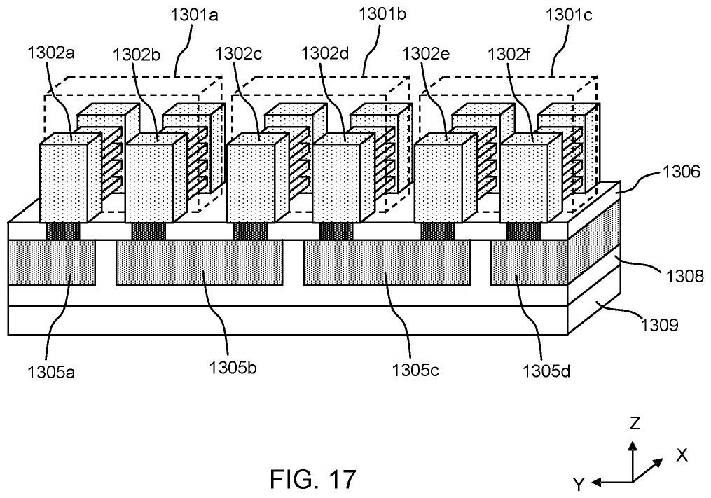

FIG. 17 shows an exemplary embodiment of a transistor structure constructed according to the invention. This embodiment shows multiple complementary transistors, as shown in FIG. 14. The embodiment includes control gates 1301a-c, P-channel devices 1302d and 1302e, and N-channel devices 1302b, 1302c, and 1302f. The power lines 1305a and 1305c are connected to VDD, and the power lines 1305b and 1305d are connected to VSS. The power lines 1305a-d are located under the transistor devices to reduce the silicon area. Using this structure, a very large scale of logic gates can be formed on top of the power lines.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A transistor structure, comprising:
a conductor layer divided into a plurality of separate conductor regions; and
a plurality of lateral transistors formed on top of the plurality of separate conductor regions, respectively, wherein each lateral transistor comprises a source, a drain, and a gate region, and wherein at least one of the source, drain, and gate regions of each lateral transistor is conductively coupled underneath to its respective conductor region.

2. The transistor structure of claim 1, wherein the at least one of the source, drain, and gate regions of the each lateral transistor directly contacts its respective conductor region to provide conductive coupling.

3. The transistor structure of claim 1, wherein the at least one of the source, drain, and gate regions of the each lateral transistor contacts its respective conductor region through a conductive contact to provide conductive coupling.

4. The transistor structure of claim 1, wherein a first portion of conductor regions are coupled to VDD, and a second portion of conductor regions are coupled to VSS.

5. The transistor structure of claim 4, wherein a first portion of lateral transistors located on top of the first portion of conductor regions form PMOS transistors.

6. The transistor structure of claim 4, wherein a second portion of lateral transistors located on top of the second portion of conductor regions form NMOS transistors.

7. The transistor structure of claim 4, wherein the conductor regions of the first portion alternate with the conductor regions of the second portion.

8. The transistor structure of claim 1, further comprising a substrate layer under the conductor layer.

9. The transistor structure of claim 1, further comprising an isolation layer between selected source, drain, and gate regions and corresponding conductor layers underneath.

10. The transistor structure of claim 1, further comprising an isolation layer between source regions and gate regions and between drain regions and gate regions.

11. A transistor structure, comprising:
a conductor layer divided into a plurality of separate conductor regions; and
two lateral transistors formed on top of each of the plurality of separate conductor regions, respectively, wherein each lateral transistor comprises a source, a drain, and a gate region, and wherein at least one of the source, drain, and gate regions of each lateral transistor is conductively coupled underneath to its respective conductor region.

12. The transistor structure of claim 11, wherein the at least one of the source, drain, and gate regions of the each lateral transistor directly contacts its respective conductor region to provide conductive coupling.

13. The transistor structure of claim 11, wherein the at least one of the source, drain, and gate regions of the each lateral transistor contacts its respective conductor region through a conductive contact to provide conductive coupling.

14. The transistor structure of claim 11, wherein a first portion of conductor regions are coupled to VDD, and a second portion of conductor regions are coupled to VSS.

15. The transistor structure of claim 14, wherein a first portion of lateral transistors located on top of the first portion of conductor regions form PMOS transistors.

16. The transistor structure of claim 14, wherein a second portion of lateral transistors located on top of the second portion of conductor regions form NMOS transistors.

17. The transistor structure of claim 14, wherein the conductor regions of the first portion alternate with the conductor regions of the second portion.

18. The transistor structure of claim 11, further comprising a substrate layer under the conductor layer.

19. The transistor structure of claim 11, further comprising an isolation layer between selected source, drain, and gate regions, and corresponding conductor layers underneath.

20. The transistor structure of claim 11, further comprising an isolation layer between source regions and gate regions and between drain regions and gate regions.
